(19) United States
(12) Patent Application Publication
(10) Pub. No.: US 2025/0096526 A1
(43) Pub. Date: Mar. 20, 2025

(54) SEMICONDUCTOR LASER DEVICE, DISTANCE MEASUREMENT DEVICE, AND VEHICLE-MOUNTED DEVICE

(71) Applicant: SONY SEMICONDUCTOR SOLUTIONS CORPORATION, Kanagawa (JP)

(72) Inventor: Mitsunari HOSHI, Kanagawa (JP)

(21) Appl. No.: 18/728,211

(22) PCT Filed: Dec. 8, 2022
(86) PCT No.: PCT/JP2022/045254

§ 371 Date: Jul. 11, 2024

(30) Foreign Application Priority Data
Jan. 20, 2022 (JP) 2022-006848

(51) Int. Cl. H01S 5/042; G01S 7/481; H01S 5/42

(52) U.S. Cl. CPC H01S 5/04256; G01S 7/4814; H01S 5/423

(57) ABSTRACT

For example, the technique of the present disclosure reduces inductance between electrodes.

Provided is a semiconductor laser device including: a semiconductor substrate having a first principal plane and a second principal plane opposite to the first principal plane; a plurality of light-emitting units disposed on the first principal plane; a first electrode electrically connected to a first region that is one region when an active region of each of the light-emitting unit serves as a boundary; and a second electrode electrically connected to a second region that is the other region when the active region of each of the light-emitting unit serves as the boundary. The first electrode and the second electrode are stacked via an insulating film therebetween on the first principal plane along a thickness direction of the semiconductor substrate.

### TECHNICAL FIELD

The present disclosure relates to a semiconductor laser device, a distance measurement device, and a vehicle-mounted device.

### BACKGROUND ART

Distance measurement devices using various distance measurement methods (for example, the Time of Flight (TOF) method) in which the distance to an object to be measured is measured by irradiating the object to be measured with light emitted from a plurality of light-emitting units and receiving the reflected light from the object to be measured have been proposed. As a light source for distance measurement devices, a surface-emitting semiconductor laser as disclosed in PTL 1 (specifically, a vertical cavity surface emitting laser (VCSEL) is used.

### CITATION LIST

### Patent Literature

[PTL 1]
JP 2008-311491A

### SUMMARY

### Technical Problem

However, in the technique disclosed in PTL 1, a thick circuit board of 100 μm or more intervenes between the upper electrode and the lower electrode. By such a constitution, the degree of cancellation between the magnetic field formed by the current flowing in the upper electrode and the magnetic field formed by the current flowing in the lower electrode (flowing in the opposite direction to the direction of the current flowing in the upper electrode) is small. Thus, there is a problem in that the transient response characteristics of a laser can be poor without reducing the inductance between electrodes.

The present disclosure has an object to provide a semiconductor laser device having a constitution with reduced inductance between electrodes, a distance measurement device, and a vehicle-mounted device.

### Solution to Problem

For example, the present disclosure is a semiconductor laser device including:
a semiconductor substrate having a first principal plane and a second principal plane opposite to the first principal plane,
a plurality of light-emitting units disposed on the first principal plane,
a first electrode electrically connected to a first region that is one region when an active region of each of the light-emitting unit serves as a boundary, and
a second electrode electrically connected to a second region that is the other region when the active region of each of the light-emitting unit serves as the boundary,
wherein
the first electrode and the second electrode are stacked via an insulating film therebetween on the first principal plane along a thickness direction of the semiconductor substrate.

The present disclosure may be a distance measurement device having such a semiconductor laser device and a vehicle-mounted device having the distance measurement device.

### BRIEF DESCRIPTION OF DRAWINGS

FIG. 1 is a diagram to which reference is made when a technique related to the present disclosure is explained.

FIG. 2 is a diagram to which reference is made when a technique related to the present disclosure is explained.

FIG. 3 is a diagram to which reference is made when a technique related to the present disclosure is explained.

FIG. 4 is a diagram to which reference is made when a technique related to the present disclosure is explained.

FIG. 5 is a diagram to which reference is made when a technique related to the present disclosure is explained.

FIG. 6 is a diagram to which reference is made when a technique related to the present disclosure is explained.

FIG. 7 is a diagram to which reference is made when a technique related to the present disclosure is explained.

FIG. 8 is a diagram to which reference is made when a technique related to the present disclosure is explained.

FIGS. 9A and 9B are diagrams to which reference is made when a technique related to the present disclosure is explained.

FIGS. 10A and 10B are diagrams to which reference is made when a technique related to the present disclosure is explained.

FIG. 11 is a diagram to which reference is made when a technique related to the present disclosure is explained.

FIG. 12 is a diagram to which reference is made when a technique related to the present disclosure is explained.

FIGS. 13A and 13B are diagrams to which reference is made when issues to be considered in the present disclosure are explained.

FIG. 14 is a perspective view of a semiconductor laser device according to a first embodiment.

FIG. 15 is an exploded perspective view of the semiconductor laser device according to the first embodiment.

FIG. 16 is a top view of the semiconductor laser device according to the first embodiment.

FIG. 17 is a cross-sectional view illustrating the cross-section of the semiconductor laser device according to the first embodiment when cut along the cutting line A-A in FIG. 16.

FIG. 18 is a diagram to which reference is made when the operation of the semiconductor laser device according to the first embodiment is explained.

FIGS. 19A and 19B are diagrams to which reference is made when an example of a method for producing the semiconductor laser device according to the first embodiment is explained.

FIGS. 20A and 20B are diagrams to which reference is made when an example of a method for producing the semiconductor laser device according to the first embodiment is explained.

FIGS. 21A and 21B are diagrams to which reference is made when an example of a method for producing the semiconductor laser device according to the first embodiment is explained.

FIGS. 22A and 22B are diagrams to which reference is made when an example of a method for producing the semiconductor laser device according to the first embodiment is explained.

FIGS. 23A and 23B are diagrams to which reference is made when an example of a method for producing the semiconductor laser device according to the first embodiment is explained.

FIGS. 24A and 24B are diagrams to which reference is made when an example of a method for producing the semiconductor laser device according to the first embodiment is explained.

FIGS. 25A and 25B are diagrams to which reference is made when an example of a method for producing the semiconductor laser device according to the first embodiment is explained.

FIGS. 26A and 26B are diagrams to which reference is made when an example of a method for producing the semiconductor laser device according to the first embodiment is explained.

FIGS. 27A and 27B are diagrams to which reference is made when an example of a method for producing the semiconductor laser device according to the first embodiment is explained.

FIG. 28 is a perspective view of a semiconductor laser device according to a second embodiment.

FIG. 29 is an exploded perspective view of the semiconductor laser device according to the second embodiment.

FIG. 30 is a top view of the semiconductor laser device according to the second embodiment.

FIG. 31 is an edge view illustrating the edge surface of the semiconductor laser device according to the second embodiment when cut along the cutting line A-A in FIG. 30.

FIG. 32 is an edge view illustrating the edge surface of the semiconductor laser device according to the second embodiment when cut along the cutting line B-B in FIG. 30.

FIG. 33 is a diagram to which reference is made when the operation of the semiconductor laser device according to the second embodiment is explained.

FIG. 34 is a diagram to which reference is made when the operation of the semiconductor laser device according to the second embodiment is explained.

FIGS. 35A and 35B are diagrams to which reference is made when an example of a method for producing the semiconductor laser device according to the second embodiment is explained.

FIGS. 36A and 36B are diagrams to which reference is made when an example of a method for producing the semiconductor laser device according to the second embodiment is explained.

FIGS. 37A and 37B are diagrams to which reference is made when an example of a method for producing the semiconductor laser device according to the second embodiment is explained.

FIGS. 38A and 38B are diagrams to which reference is made when an example of a method for producing the semiconductor laser device according to the second embodiment is explained.

FIGS. 39A and 39B are diagrams to which reference is made when an example of a method for producing the semiconductor laser device according to the second embodiment is explained.

FIGS. 40A and 40B are diagrams to which reference is made when an example of a method for producing the semiconductor laser device according to the second embodiment is explained.

FIGS. 41A and 41B are diagrams to which reference is made when an example of a method for producing the semiconductor laser device according to the second embodiment is explained.

FIGS. 42A and 42B are diagrams to which reference is made when an example of a method for producing the semiconductor laser device according to the second embodiment is explained.

FIGS. 43A and 43B are diagrams to which reference is made when an example of a method for producing the semiconductor laser device according to the second embodiment is explained.

FIG. 44 is a diagram to which reference is made when the simulation results are explained.

FIG. 45 is a diagram to which reference is made when the simulation results are explained.

FIG. 46 is a diagram to which reference is made when the simulation results are explained.

FIG. 47 is a diagram to which reference is made when the simulation results are explained.

FIG. 48 is a block diagram showing an example of a schematic constitution of a vehicle control system.

FIG. 49 is an explanatory diagram showing an example of installation positions of a vehicle external information detector and an image-capturing unit.

### DESCRIPTION OF EMBODIMENTS

Hereinafter, embodiments of the present disclosure will be described with reference to the drawings. The explanation will be made in the following order.
<Technique Related to Present Disclosure>
<Issues to be Considered in Present Disclosure>
<First Embodiment>
<Second Embodiment>
<Modification Examples>
<Application Examples>

The embodiments to be described below are preferred specific examples of the present disclosure, and the content of the present disclosure is not limited to these embodiments. In the following explanations, constituent elements having substantially the same functional configurations are indicated by the same reference numerals, and redundant explanations thereof are optionally omitted. To prevent the illustration from becoming complicated, reference symbols or numbers may be assigned to only a part of the constitutions, or the illustration may be simplified or enlarged/reduced in some cases. For convenience of explanation, directions such as left, right, up, down, or the like are defined, but the content of the present disclosure is not limited to these directions.

### Technique Related to Present Disclosure

First, in order to facilitate understanding of the present disclosure, the technique related to the present disclosure (hereinafter appropriately abbreviated to a related technique) will be described. The present applicant has proposed an illumination device applicable to distance measurement devices or the like as a technique related to the present disclosure. The content of such an illumination device has been published as WO 2021/075340, and the content disclosed in the official gazette is applicable to the present disclosure.

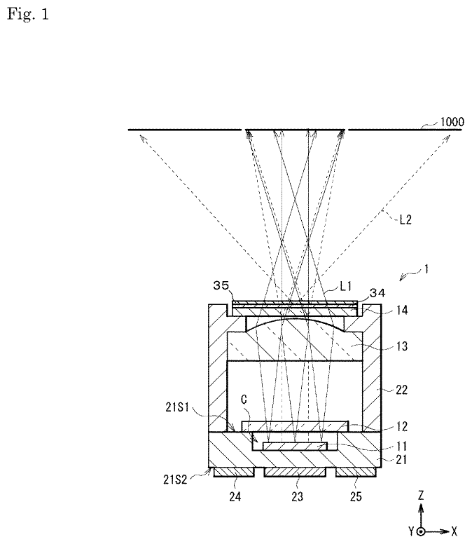

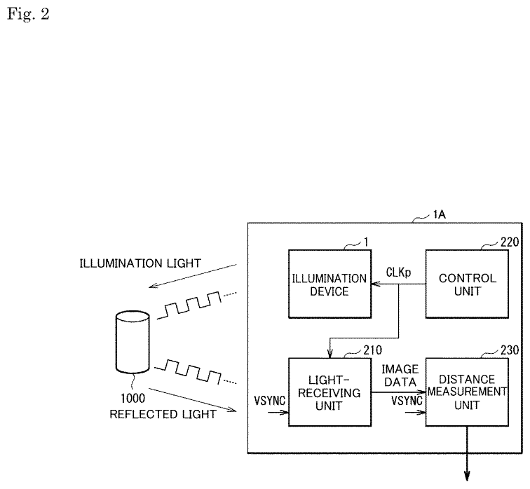

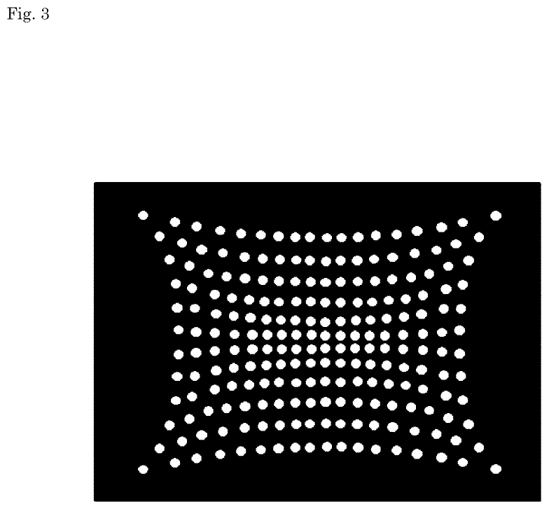

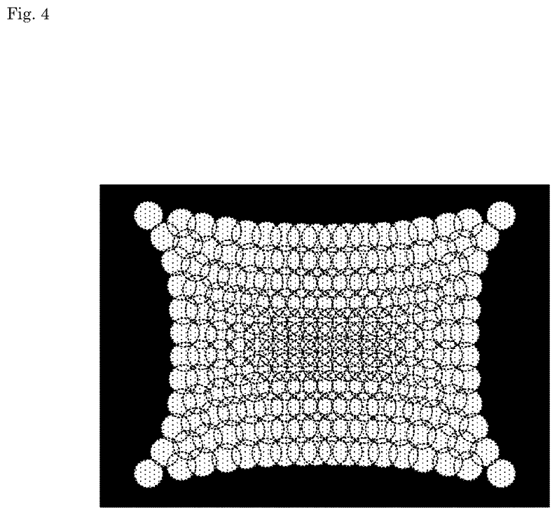

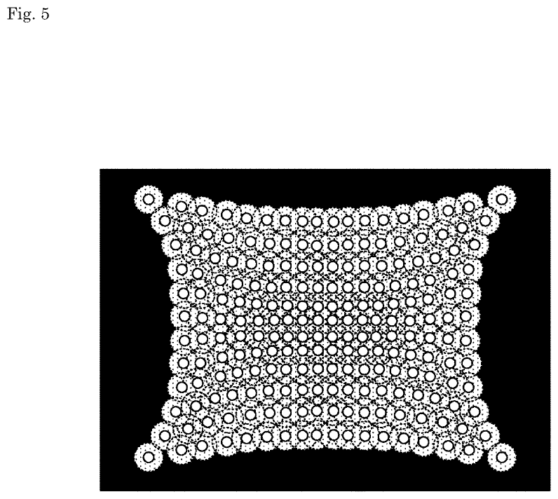

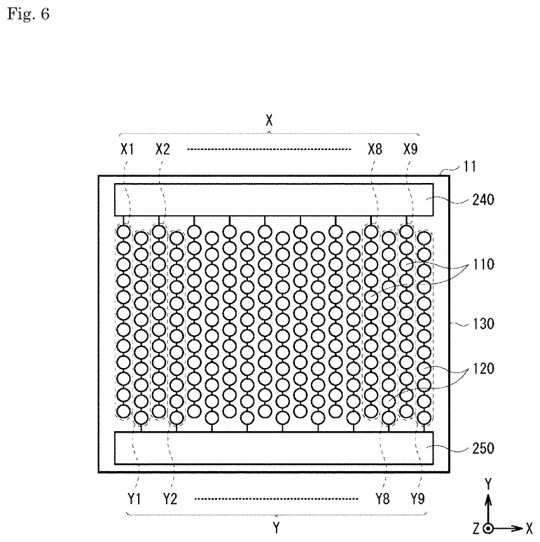

Related techniques are schematically explained. FIG. 1 is a sectional view schematically representing an example of a schematic constitution of an illumination device (illumination device 1) of a related technique. FIG. 2 is a block diagram representing a schematic constitution of a distance measurement device (distance measurement device 1A) provided with the illumination device 1 illustrated in FIG. 1. The illumination device 1 according to the related technique shapes, for example, the beam shape of the beam L2 of beams L1 and L2 emitted from a light-emitting element 11 having a plurality of light-emitting units (light-emitting units 110 and 120 (see FIG. 6)) and irradiates an object 1000 to be irradiated by, for example, spot irradiation as illustrated in FIG. 3, uniform irradiation as illustrated in FIG. 4, and simultaneous irradiation as illustrated in FIG. 5.

For example, the illumination device 1 has a light-emitting element 11, a microlens array 12, a collimator lens 13, and a diffraction element 14. The microlens array 12, the collimator lens 13, and the diffraction element 14 are arranged on the light path of the light (light L1 and light L2) emitted from the light-emitting element 11, for example, in the stated order. The light-emitting element 11 and the microlens array 12 are held by, for example, a holding part 21, and the collimator lens 13 and the diffraction element 14 are held by, for example, a holding part 22. For example, the holding part 21 has one cathode electrode portion 23 and two anode electrode units 24 and 25, for example, on the surface 21S2 opposite to the surface 21S1 holding the light-emitting element 11 and the microlens array 12. Hereinafter, the members constituting the illumination device 1 will be described in detail.

For example, the light-emitting element 11 is a surface-emitting semiconductor laser-having a plurality of light-emitting units. For example, a plurality of light-emitting units has a constitution in which a plurality of light-emitting units used for spot irradiation (a plurality of light-emitting units 110 for spot irradiation) and a plurality of light-emitting units used in uniform irradiation (a plurality of light-emitting units 120 for uniform irradiation) are arranged, for example, in arrays on a substrate 130. The plurality of light-emitting units 110 and the plurality of light-emitting units 120 are electrically separated from each other.

The plurality of light-emitting units 110 and the plurality of light-emitting units 120 are each electrically connected to each other. Specifically, for example, as illustrated in FIG. 6, a plurality of light-emitting units 110 are constituted of a plurality (for example, the number is 9 in FIG. 6) of light-emitting unit groups X (light-emitting unit groups X1 to X9) composed of n (for example, n=12 in FIG. 6) light-emitting units 110 extending in one direction (for example, the Y-axis direction). Similarly, a plurality of light-emitting units 120 are constituted of a plurality (for example, the number is 9 in FIG. 6) of light-emitting unit groups Y (light-emitting unit groups X1 to X9) composed of m (for example, m=9 in FIG. 6) light-emitting units 120 extending in one direction (for example, the Y-axis direction). For example, each of the light-emitting unit groups X1 to X9 and light-emitting unit groups Y1 to Y9 are alternately arranged on a rectangular substrate 130, as illustrated in FIG. 6. For example, the light-emitting unit groups X1 to X9 are electrically connected to an electrode pad 240 disposed along one side of the substrate 130, and, for example, the light-emitting unit groups Y1 to Y9 are electrically connected to an electrode pad 250 disposed along another side opposite to the one side of the substrate 130. FIG. 6 shows an example in which light-emitting unit groups X1 to X9 and Y1 to Y9 are alternately arranged, but the embodiments are not limited thereto. For example, each of the number of the plurality of light-emitting units 110 and the plurality of light-emitting units 120 may be any arrangement depending on the number and positions of the desired luminous point spots and the amount of the light output. As one example, the arrays of the plurality of light-emitting units 120 may be arranged every two rows of arrays of the plurality of light-emitting units 110.

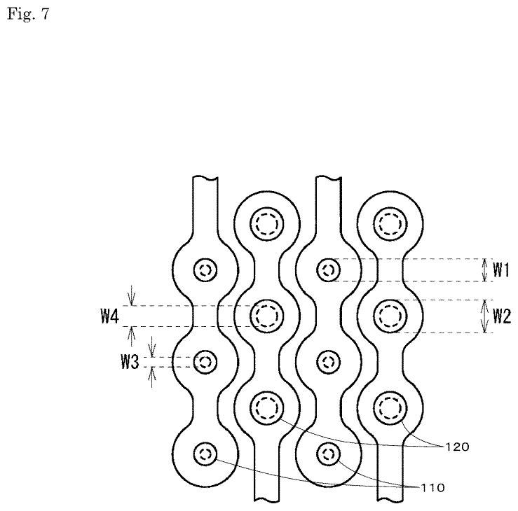

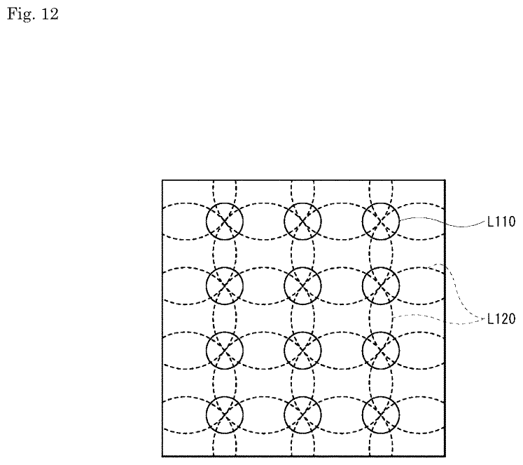

FIG. 7 is a view enlarging some arrays of the plurality of light-emitting units 110 and the plurality of light-emitting units 120 illustrated in FIG. 6. It is preferred that the plurality of light-emitting units 110 and the plurality of light-emitting units 120 have mutually different luminous areas (OA diameters W3 and W4). Specifically, the luminous area (OA diameter W3) of the plurality of light-emitting units 110 for spot irradiation is preferably lower than the luminous area (OA diameter W4) of the plurality of light-emitting units 120 for uniform irradiation. This allows the light beams for spot irradiation (laser beam L110, see FIG. 12) emitted from the plurality of light-emitting units 110 to be focused to a smaller size, enabling irradiation of the object with a smaller spot. Furthermore, the light beam (laser beam L120, see FIG. 12) for uniform irradiation emitted from the plurality of light-emitting units 120 can irradiate a wider range, enabling more uniform and higher output uniform irradiation to an object 1000 to be irradiated. Along with this, the opening width W1 of the wirings to which the plurality of light-emitting units 110 are respectively connected is smaller than the opening width W2 of the wirings to which the plurality of light-emitting units 120 are respectively connected.

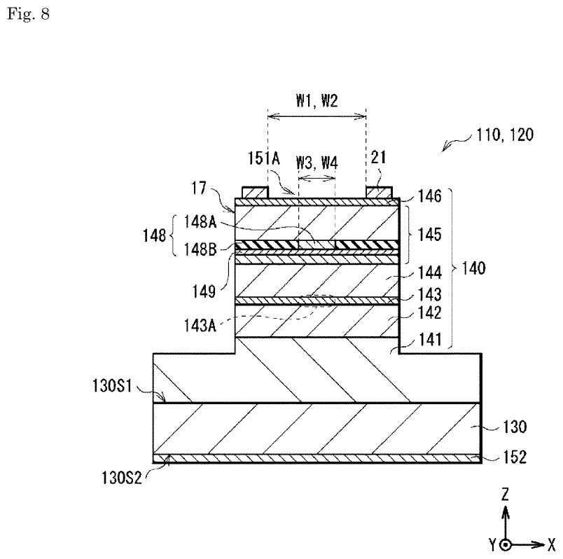

FIG. 8 is a view schematically representing an example of a sectional constitution of light-emitting units (light-emitting units 110 and 120) of the light-emitting element 11. The light-emitting element 11 is a surface-emission-type surface-emitting semiconductor laser. The light-emitting units 110 and 120 each have a semiconductor layer 140 that includes a lower distributed Bragg reflector (DBR) layer 141, a lower spacer layer 142, an active layer 143, an upper spacer layer 144, an upper DBR layer 145, and a contact layer 146 in this order on one surface (surface (surface 130S1)) of the substrate 130. The upper part of this semiconductor layer 140, specifically, a part of the lower DBR layer 141, the lower spacer layer 142, the active layer 143, the upper spacer layer 144, the upper DBR layer 145, and the contact layer 146 forms a columnar mesa part 147.

For example, the substrate 130 is an n-type GaAs substrate. Examples of n-type impurities include silicon (Si), selenium (Se), and the like. For example, the semiconductor layer 140 is each constituted of an AlGaAs-based compound semiconductor. An AlGaAs-based compound semiconductor means a compound semiconductor that contains at least aluminum (Al) and gallium (Ga) among the group 3B elements in the short period periodic table and at least arsenic (As) among the group 5B elements in the short period periodic table.

The lower DBR layer 141 is composed of low refractive index layers and high refractive index layers (all not shown) that are alternately stacked. For example, the low refractive index layer is composed of an n-type Al_{x·1}Ga_{1·x1}As (0<x1<1) with a thickness of λ₀/4ₙ₁ (λ is a light emission wavelength, and n1 is a refractive index). For example, the high refractive index layer is composed of an n-type Al_{x·2}Ga_{1·x2}As (0<x2<x1) with a thickness of λ₀/4ₙ₂ (n2 is a refractive index).

For example, the lower spacer layer 142 is composed of an n-type Al_{x·3}Ga_{1·x3}As (0<x3<1). For example, the active layer 143 is composed of an undoped n-type Al_{x·4}Ga_{1 x4}As (0<x4<1). For example, the upper spacer layer 144 is composed of a p-type Al_{x·5}Ga_{1·x5}As (0<x5<1). Examples of p-type impurities include zinc (Zn), magnesium (Mg), beryllium (Be), and the like.

The upper DBR layer 145 is formed by alternately stacking low refractive index layers and high refractive index layers (both not shown). For example, the low refractive index layer is composed of a p-type Alₓ₆Ga_{1·x6}As (0<x6<1) with a thickness of λ₀/4n₃ (n₃ is a refractive index). For example, the high refractive index layer is composed of a p-type Alₓ₇Ga_{1·x7}As (0<x7<x6) with a thickness of λ₀/4n₄ (n₄ is a refractive index). For example, the contact layer 16 is formed of a p-type Alₓ₈Ga_{1·x8}As (0<x8<1).

The light-emitting element 11 is further provided with a current constriction layer 148 and a buffer layer 149. The current constriction layer 148 and the buffer layer 149 are arranged in the upper DBR layer 145.

The current constriction layer 148 is formed at a position separated from the active layer 143 in the relationship with the buffer layer 149. For example, the current constriction layer 148 is disposed, instead of a low refractive index layer, in the upper DBR layer 145, for example, in a region of the low refractive index layer several layers away counting from the active layer 143 side. The current constriction layer 148 has a current injection region 148A and a current constriction region 148B. The current injection region 148A is formed in the central region in the plane and corresponds to the luminous areas (OA diameters W3 and W4) of the light-emitting units 110 and 120 described above. The current constriction region 148B is formed in the periphery of the current injection region 148A; that is, the outer peripheral region of the current constriction layer 148 and has a cyclic shape.

For example, the current injection region 148A is constituted of a p-type Alₓ₉Ga_{1·x9}As (0.98≤x9≤1). For example, the current constriction region 148B is configured to contain aluminum oxide (Al₂O₃), and, for example, obtained by oxidizing the layer to be oxidized (not illustrated) constituted by p-type Alₓ₉Ga_{1·x9}As from the side surface of the mesa part 17. Due to this feature, the current constriction layer 148 has a function of constricting currents.

The buffer layer 149 is formed closer to the active layer 143 in the relationship with the current constriction layer 148. The buffer layer 149 is formed adjacent to the current constriction layer 148. For example, the buffer layer 149 is formed in contact with the surface (lower surface) on the active layer 143 side in the current constriction layer 148, as illustrated in FIG. 8. It is noted that a thin layer with a thickness of, for example, several nanometers may be formed between the current constriction layer 148 and the buffer layer 149. For example, the buffer layer 149 is disposed, instead of a high refractive index layer, in the upper DBR layer 145, for example, in a region of the high refractive index layer several layers away counting from the current constriction layer 148.

The buffer layer 149 has an unoxidized region and an oxidized region (both not illustrated). The unoxidized region is mainly formed in the in-plane center region, and, for example, is formed in a portion in contact with the current injection region 148A. The oxidized region is formed at the periphery of the unoxidized region 19A and has a cyclic shape. The oxidized region is mainly formed in the outer periphery region in the plane, and, for example, is formed in a portion in contact with the current constriction region 148B. The oxidized region is formed biasedly toward the current constriction layer 148 side in the part other than the part corresponding to the outer periphery of the buffer layer 149.

The unoxidized region is configured by a semiconductor material containing Al, and, for example, p-type Alₓ₁₀Ga_{1 x10}As (0.85<x10≤0.98) or p-type InAlₓ₁₁GaAs (0.85<x11≤0.98). For example, an oxide region is configured to include aluminum oxide (Al₂O₃), and, for example, is obtained by oxidizing a layer to be oxidized (not illustrated) constituted of p-type Alₓ₁₀Ga_{1·x10}As or p-type InAlₓ₁₁GaAs from the side surface side and the side of the layer to be oxidized of the mesa part 147. The layer to be oxidized of this buffer layer 149 is composed of materials and thicknesses that show an oxidation rate more rapid than the lower DBR layer 141 and the upper DBR layer 145 and slower than the layer to be oxidized of the current constriction layer 148.

On the top surface (the top surface of the contact layer 146) of the mesa part 147, a ring-shaped upper electrode 151 having an opening (light outlet port 151A) is formed at least in the region opposite to the current injection region 148A. On the side surface and the surrounding surface of the mesa part 147, an insulating layer (not illustrated) is formed. The upper electrode 151 is connected to an electrode pad 240 and an electrode pad 250 for every light-emitting unit groups X1 to X9 and the light-emitting unit groups Y1 to Y9 described above by a wiring 111 and a wiring 112 illustrated in FIG. 7, respectively. The electrode pad 240 and the electrode pad 250 are each connected to an electrode unit disposed on the surface (surface 21S1) of the holding part 21, which will be described below, by, for example, wire bonding, and electrically connected to the anode electrode unit 24 and the anode electrode unit 25 disposed on the back surface (surface 21S2) of the holding part 21. In addition, on the other surface (back surface (surface 130S2)) of the substrate 130, the lower electrode 152 is disposed. For example, the lower electrode 152 is electrically connected to a cathode electrode unit 23 disposed on the back surface (surface 21S2) of the holding part 21, which will be described below. In the present embodiment, an example in which a cathode electrode is formed as a common electrode, and anode electrodes are separately formed is illustrated, but an anode electrode may be formed as a common electrode, and cathode electrodes may be separately formed depending on the structure of the light-emitting element 11.

Here, the upper electrode 151, the electrode pad, and the connection part are, for example, constituted of stacking titanium (Ti), platinum (Pt), and gold (Au) in this order, and are electrically connected to the contact layer 146 of the upper part of the mesa part 147. The lower electrode 152 has a structure in which, for example, an alloy of gold (Au) and germanium (Ge), nickel (Ni), and gold (Au) are stacked sequentially from the substrate 130 side and electrically connected to the substrate 130.

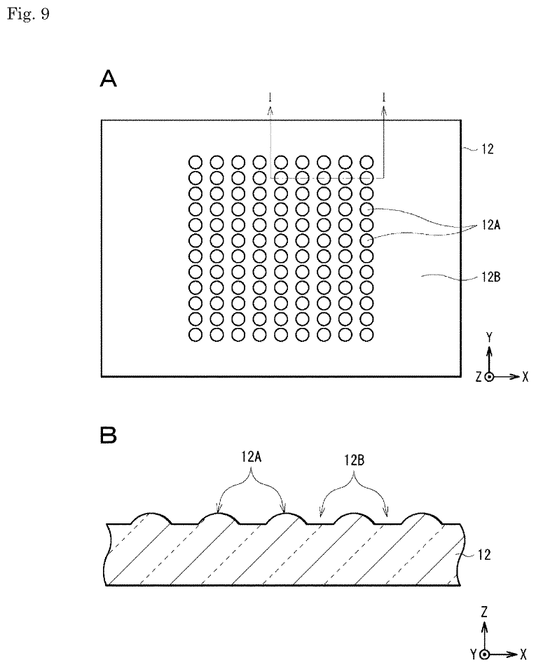

For example, the microlens array 12 shapes at least one beam shape of light beams (laser beam L110 and laser beam L120) emitted from a plurality of light-emitting units 110 for spot irradiation and a plurality of light-emitting units 120 for uniform irradiation and emits the light beam. FIG. 9A schematically illustrates one example of a planar structure of a microlens array 12, and FIG. 9B schematically illustrates a sectional structure of the microlens array 12 along the line I-I illustrated in FIG. 9A. The microlens array 12 has a plurality of microlens arranged in an array and has a plurality of lens parts 12A and a parallel flat plate portion 12B.

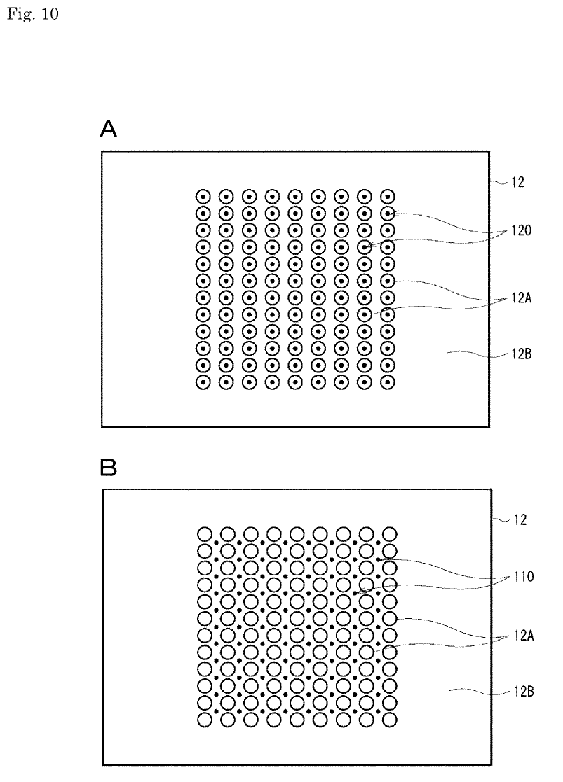

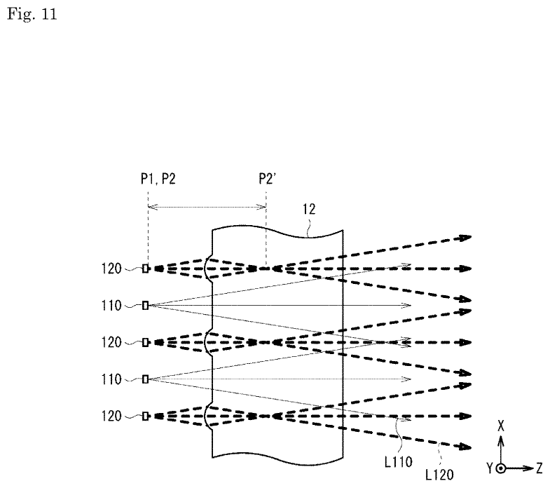

In the related art, the microlens array 12 is arranged so that the lens parts 12A face the plurality of light-emitting units 120 for uniform irradiation, as illustrated in FIG. 10A and the parallel flat plate portion 12B face the plurality of light-emitting units 110 for spot irradiation, as illustrated in FIG. 10B. This allows the laser beam L120 emitted from the plurality of light-emitting units 120 to be refracted on the lens surface of the lens parts 12A and to form a virtual light-emitting point P2′, for example, in the microlens array 12 as illustrated in FIG. 11. That is, the light-emitting point P2 of the plurality of light-emitting units 120 located at the same height as the light-emitting point P1 of the plurality of light-emitting units 110 is shifted in the axis direction (for example, the Z-axis direction) of the light beams (laser beam L110 and laser beam L120) emitted from the plurality of light-emitting units 110 and the plurality of light-emitting units 120.

Accordingly, by switching the light emission of the plurality of light-emitting units 110 and the plurality of light-emitting units 120, the laser beam L110 emitted from the plurality of light-emitting units 110 forms a spot-shaped irradiation pattern, for example, as illustrated in FIG. 3 or 12. For example, the laser beam L120 emitted from the plurality of light-emitting units 120 is superimposed on the laser beam L120 emitted from light-emitting units 120 that are partly adjacent to each other, as illustrated in FIG. 4 or FIG. 12, thereby forming an irradiation pattern that irradiates a predetermined range with substantially uniform light intensity. In the illumination device 1, switching between spot irradiation and uniform irradiation becomes possible by switching the light emission of the plurality of light-emitting units 110 and the light emission of the plurality of light-emitting units 120.

In FIG. 11, an example in which the microlens array 12 functions as a relay lens, but the embodiments are not limited thereto. For example, the virtual light-emitting point P2′ of the plurality of light-emitting units 120 may be formed between the light-emitting unit 120 and the microlens array 12.

The collimator lens 13 outputs the laser beam L110 emitted from the plurality of light-emitting units 110 and the laser beam L120 emitted from the plurality of light-emitting units 120 as a substantially parallel light beam. For example, the collimator lens 13 is a lens for collimating each of the laser beam L110 and the laser beam L120 outputted from the microlens array 12 and couples the collimated light beam to the diffraction element 14.

The diffraction element 14 divides and outputs each of the laser beam L110 emitted from the plurality of light-emitting units 110 and the laser beam L120 emitted from the plurality of light-emitting units 120. For example, as the diffraction element 14, a diffraction optical element (DOE) that splits the laser beam L110 emitted from the plurality of light-emitting units 110 and the laser beam L120 emitted from the plurality of light-emitting units 120 into 3×3. By disposing the diffraction element 14, the respective luminous fluxes of the laser beam L110 and the laser beam L120 can be tiled to, for example, increase the spot number in spot irradiation or enlarge the irradiation area in the uniform irradiation.

The holding part 21 and the holding part 22 are for holding the light-emitting element 11, the microlens array 12, the collimator lens 13, and the diffraction element 14. Specifically, the holding part 21 holds the light-emitting element 11 in a recessed portion C disposed on the top surface (surface 21S1) and holds the microlens array 12 along the surface 21S1. The holding part 22 holds the collimator lens 13 and the diffraction element 14. The microlens array 12, the collimator lens 13, and the diffraction element 14 are respectively held by the holding part 21 and the holding part 22 by, for example, an adhesive. The holding part 21 and the holding part 22 are connected to each other such that the light beam L1 (specifically, a laser beam L110) and the light beam L2 (specifically, a laser beam L120) emitted from the light-emitting element 11 is made incident on a predetermined position of the microlens array 12, and the light beams L1 and L2 passing through the collimator lens 13 is made to be a substantially parallel light beam.

A plurality of electrode units is provided on the back surface (surface 21S2) of the holding part 21. Specifically, on the surface 21S2 of the holding part 21, a cathode electrode unit 23 common to the plurality of light-emitting units 110 for spot irradiation and the plurality of light-emitting units 120 for uniform irradiation, an anode electrode unit 24 of the plurality of light-emitting units 110 for spot irradiation, and an anode electrode unit 25 of the plurality of light-emitting units 120 for uniform irradiation are disposed.

The constitution of the plurality of electrode units disposed on the surface 21S2 of the holding part 21 is not limited to that described above. For example, cathode electrode units for the plurality of light-emitting units 110 for spot irradiation and the plurality of light-emitting units 120 for uniform irradiation may be formed separately, or an anode electrode unit of the plurality of light-emitting units 110 for spot irradiation and the plurality of light-emitting units 120 for uniform irradiation may be formed as a common electrode unit. FIG. 1 illustrates an example in which the microlens array 12 is held by the holding part 21, but the embodiments are not limited thereto. For example, the microlens array 12 may be held by the holding part 22. The collimator lens 13 and the diffraction element 14 may be held by the holding part 21.

### Issues to be Considered in Present Disclosure

While taking into account the related techniques described above, issues to be considered in the present disclosure will be explained. When the light-emitting unit 110 (which may be the light-emitting unit 120) emits light, currents flow each in the upper electrode 151 and the lower electrode 152 in opposite directions; in other words, currents in opposite directions flow above and below the substrate 130. Here, when the thickness of the substrate 130 is large (for example, 100 μm or larger), cancellation between magnetic fields formed by the current flowing in each of the surfaces above or below the substrate 130 becomes small. Because cancellation between magnetic fields becomes small, the inductance cannot be reduced.

If the inductance is large, variations occur in the light emission timing of each light-emitting unit. For example, in the case of the structure illustrated in FIG. 6, a light-emitting unit 110 on the side closer to the electrode pad 240 among the plurality of light-emitting units 110 constituting the light-emitting unit group X1 is not so affected by inductance and starts up quickly. In contrast, a light-emitting unit 110 on the side farther from the electrode pad 240 among the plurality of light-emitting units 110 constituting the light-emitting unit group X1 is affected by inductance and starts up slowly. As such, the greater the distance from the electrode pad 240, the greater the delay in light-emitting timing. The same applies to the plurality of light-emitting units 120 constituting the light-emitting unit group Y. The variation in light-emitting timings among the light-emitting units results in a decrease in distance measurement accuracy when the illumination device is applied to a distance measurement device.

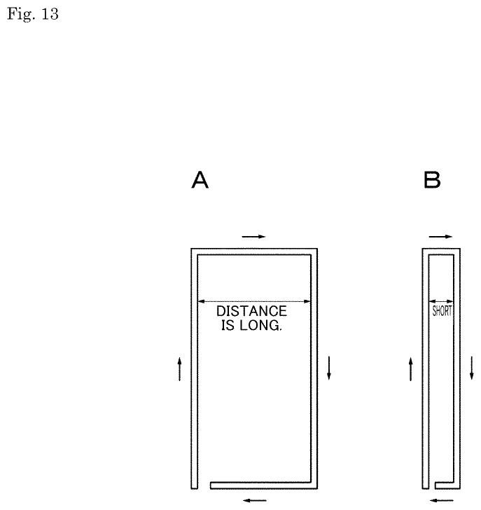

In the present disclosure, variation in light-emitting timings is eliminated as much as possible by minimizing the inductance as much as possible, thereby increasing the transient response characteristics of laser beams. FIGS. 13A and 13B are diagrams in which current paths are schematically illustrated by arrows. As illustrated in FIG. 13A, as the distance between the paths for currents flowing in the opposing directions is larger, the cancellation between magnetic fields formed by respective currents is smaller. Thus, the inductance is not reduced. Thus, as disclosed in FIG. 13B, the distance between the paths of the currents flowing in the opposing directions is reduced in the present disclosure, thereby increasing the cancellation between magnetic fields formed by respective currents and effectively reducing the inductance. This eliminates the variation in light-emitting timings as much as possible and increases the transient response characteristics of laser beams. Furthermore, when the semiconductor laser device is used as a light source of a distance measurement device, distance measurement accuracy is increased. With the above points in mind, the details of the present disclosure will be explained by referring to the embodiments.

### First Embodiment

### Constitution Example of Semiconductor Laser Device

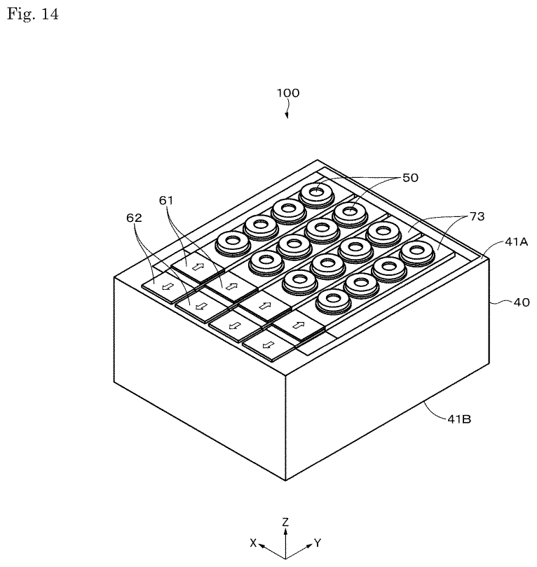

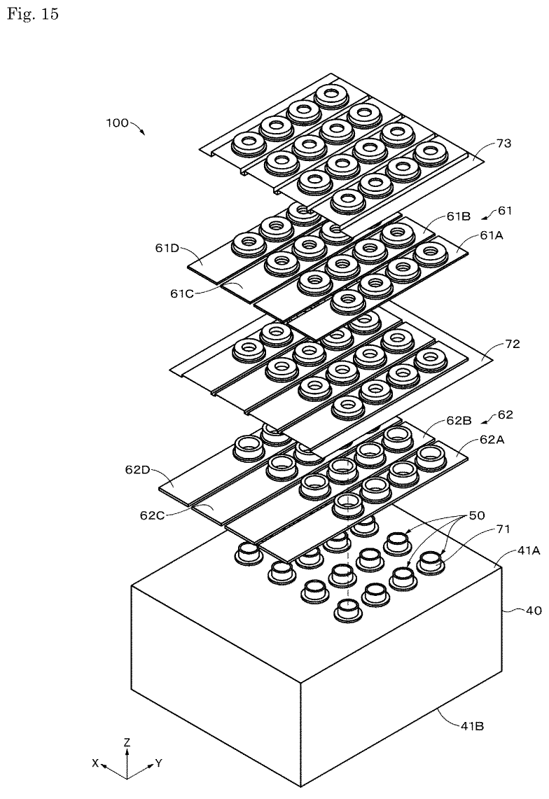

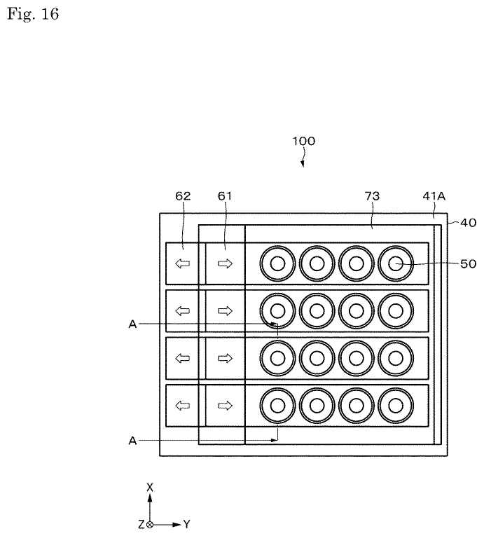

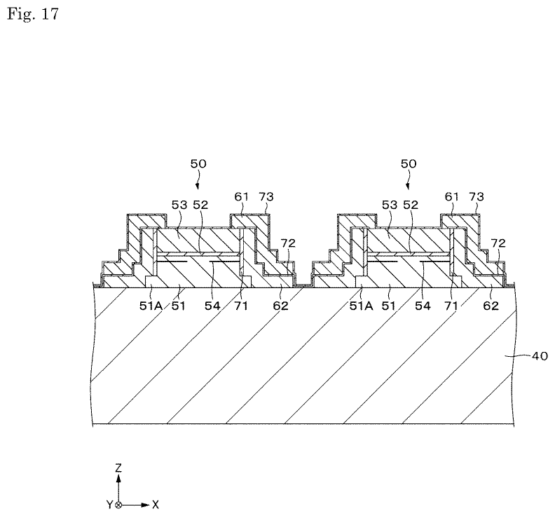

A semiconductor laser device (semiconductor laser device 100) according to the first embodiment is explained with reference to FIGS. 14 to 17. FIG. 14 is a perspective view of the semiconductor laser device 100. FIG. 15 is an exploded perspective view of the semiconductor laser device 100. FIG. 16 is a top view of the semiconductor laser device 100. FIG. 17 is a cross-sectional view when the semiconductor laser device 100 is cut along the cutting line A-A in FIG. 16.

The semiconductor laser device 100 schematically has a semiconductor substrate 40, a plurality of light-emitting units 50, an upper electrode 61 (one example of the first electrode according to the present embodiment), a lower electrode 62 (one example of the second electrode according to the present embodiment), a first protective film (insulating film) 71, a second protective film (insulating film) 72, and a third protective film (insulating film) 73. The semiconductor substrate 40 has a first principal plane 41A, which has a substantially rectangular shape, and a second principal plane 41B, which has a substantially rectangular shape and is the back side opposite to the first principal plane 41A. The first principal plane 41A is located at the upper side in the Z direction, and the second principal plane 41B is located at the lower side in the Z direction. A plurality of light-emitting units 50 are arranged on the first principal plane 41A, and the first protective film 71 is formed on the peripheral surface (side surface) of the light-emitting unit 50. With respect to the light-emitting unit 50, the lower electrode 62, the second protective film 72, the upper electrode 61, and the third protective film 73 are arranged to be stacked in this order.

### (Semiconductor Substrate)

The semiconductor substrate 40 is preferably a semi-insulating substrate (semi insulator (SI) substrate). If the semiconductor substrate 40 is conductive, the current flowing in the light-emitting unit 50 may cause some current leakage, and the leaked current may enter into the semiconductor substrate 40. For the substrate 40, for example, a GaAs substrate is used. In addition, a substrate on which the crystals of a laser-emitting layer are grown, such as a GaN substrate, a sapphire substrate, and an InP substrate, may be used. The material of the semiconductor substrate 40 is determined depending on the wavelength to be emitted. Thus, the type of semiconductor substrate applied is normally selected from that perspective.

### (Light-Emitting Unit)

The plurality of light-emitting units 50 are disposed on the first principal plane 41A. The light-emitting unit 50 has a structure slightly protruding with respect to the first principal plane 41A. In the present embodiment, four light-emitting units 50 are disposed in the X direction of the first principal plane 41A, four light-emitting units 50 are disposed in the Y direction, and a total of 16 light-emitting units 50 are disposed. At least two light-emitting units 50 are required, and the number and arrangement form of the light-emitting units 50 can be changed as appropriate.

As illustrated in FIG. 17, the light-emitting unit 50 schematically has a structure in which a lower DBR layer 51, an active layer 52, and an upper DBR layer 53 are stacked from the first principal plane 41A side of the semiconductor substrate 40. In a part of the light-emitting unit 50 (for example, an area near the upper periphery of the lower DBR layer 51), oxidative constriction occurs, whereby an oxidized constriction portion 54 is formed. As the materials of these constitutions, materials mentioned as examples explained in the explanation of the related techniques described above can be applied. The structure of the light-emitting unit 50 illustrated in FIG. 17 is a schematic structure and may include other components than the exemplified structure.

In the present embodiment, when the active layer 52, which is an active region of the light-emitting unit 50, is defined as the boundary, the upper DBR layer 53, which is the upper region, corresponds to the first region, and the lower DBR layer 51, which is the lower region and includes a part in contact with the first principal plane 41A, corresponds to the second region. The first and second regions may be regions located in the left-right direction instead of the up-and-down direction.

The lower side of the lower DBR layer 51 (including the area in contact with the first principal plane 41A) forms a wide portion 51A with a width (the length in the X direction) wider than the widths of the upper side of the lower DBR layer 51, the active layer 52, and the upper DBR layer 53. A first protective film 71 is formed on the peripheral surface of the light-emitting unit 50 (specifically, the peripheral surface on the upper side of the lower DBR layer 51, the peripheral surface of the active layer 52, and the peripheral surface of the upper DBR layer 53), excluding the peripheral surface of the wide portion 51A.

The lower electrode 62 is formed so as to be in contact with the surface of the first protective film 71 and electrically connected to the surface of the wide portion 51A of the lower DBR layer 51. A second protective film 72 is formed on the lower electrode 62, and an upper electrode 61 is formed on the upper side of the second protective film 72. That is, the upper electrode 61 and the lower electrode 62 are stacked on the first principal plane 41A via the second protective film 72, which is an insulating film interposed therebetween, along the thickness direction of the semiconductor substrate 40. The upper electrode 61 is electrically connected to the upper DBR layer 53. For example, the upper electrode 61 is formed to be in contact with the upper part of the upper DBR layer 53.

A third protective film 73 is disposed on the upper side of the upper electrode 61. The third protective film 73 is formed to prevent foreign matters, such as moisture, from entering the inside of the semiconductor laser device 100.

### (Upper Electrode and Lower Electrode)

The upper electrode 61 and the lower electrode 62 are electrodes electrically connected to each light-emitting unit 50. The upper electrode 61 and the lower electrode 62 are arranged along the substantially same direction (the Y direction in the present embodiment) in the plane of the first principal plane 41A. For injecting current to each of the upper electrode 61 and the lower electrode 62 from the exterior of the semiconductor substrate 40, the edges of the upper electrode 61 and the lower electrode 62 extend to the vicinity of the periphery of the semiconductor substrate 40. As illustrated in FIGS. 14 and 16, the edge of the lower electrode 62 extends closer to the periphery of the semiconductor substrate 40 than the edge of the upper electrode 61.

The upper electrode 61 is connected, for example, by wire bonding, to an anode electrode connected to a laser driver (all not illustrated). The lower electrode 62 is connected, for example, by wire bonding, to a cathode electrode connected to a laser driver (all not illustrated).

The direction of current flowing in the upper electrode 61 is opposite to the direction of current flowing in the lower electrode 62. For example, the current flows in the +Y direction in the upper electrode 61, and the current flows in the −Y direction in the lower electrode 62. In FIGS. 14 and 16, current directions are indicated by arrows.

As the materials of the upper electrode 61 and the lower electrode 62, metals with low electric resistance are used. For example, Au and Cu are used as the materials for the upper electrode 61 and the lower electrode 62. Including the viewpoint that it is preferred to have corrosion resistance to protect the electrodes, Au is preferred as a material for the upper electrode 61 and the lower electrode 62. However, since it is sufficient that the materials have electric conductivity, the materials for the upper electrode 61 and the lower electrode 62 are not limited to metal materials.

In the present embodiment, the upper electrode 61 extends in the Y direction and includes upper electrodes 61A, 61B, 61C, and 61D, which are separated from one another. The lower electrode 62 extends in the Y direction and includes lower electrodes 62A, 62B, 62C, and 62D, which are separated from one another.

The upper electrode 61A and the lower electrode 62A are in parallel in the in-plain direction (the Y direction of the present embodiment) of the first principal plane 41A and formed along the thickness direction (the Z direction of the present embodiment) of the semiconductor substrate 40. The upper electrode 61A and the lower electrode 62A are electrodes each connected to four light-emitting units 50 located at the front side in the X direction (closer to the origin) and arranged along the Y direction.

The upper electrode 61B and the lower electrode 62B are in parallel with the in-plane direction of the first principal plane 41A and are formed along the thickness direction of the semiconductor substrate 40. The upper electrode 61B and the lower electrode 62B are electrodes each connected to four light-emitting units 50 located in the second row from the front side in the X direction and arranged along the Y direction.

The upper electrode 61C and the lower electrode 62C are in parallel with the in-plane direction of the first principal plane 41A and are formed along the thickness direction of the semiconductor substrate 40. The upper electrode 61C and the lower electrode 62C are electrodes each connected to four light-emitting units 50 located in the third row from the front side in the X direction and arranged along the Y direction.

The upper electrode 61D and the lower electrode 62D are in parallel with the in-plane direction of the first principal plane 41A and are formed along the thickness direction of the semiconductor substrate 40. The upper electrode 61D and the lower electrode 62D are electrodes each connected to four light-emitting units 50 located in the fourth row from the front side in the X direction and arranged along the Y direction.

### (Protective Film)

As the first protective film 71, the second protective film 72, and the third protective film 73, materials with insulating properties are used. Suitable examples of these protective films include silicon nitride (Si₃N₄) or silicon oxide (SiO₂), which are compatible with semiconductor processes. It is preferred that the third protective film 73 has moisture resistance. Therefore, silicon nitride, the film of which is dense, is suitable. Silicon nitride is also applicable to the first protective film 71 and the second protective film 72. Alternatively, as the second protective film 72, silicon oxide, the dielectric constant of which is smaller than silicon nitride, may be used.

### Operation of Semiconductor Laser Device

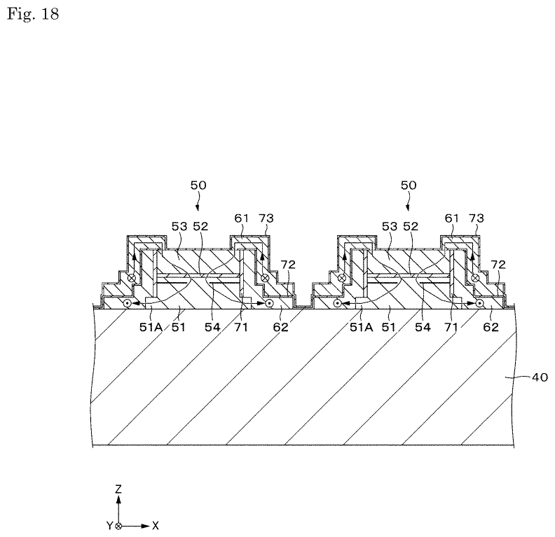

Next, the operation of the semiconductor laser device 100 according to the present embodiment will be described with reference to FIG. 18. In FIG. 18, the direction and flow of currents are indicated by arrows.

A current is supplied to the semiconductor laser device 100 by a non-illustrated laser driver. The supplied current flows in the upper electrode 61, passes through the upper DBR layer 53 and then through the active layer 52, and flows into the lower DBR layer 51. This allows the light-emitting unit 50 to emit a light beam. Here, the oxidized constriction portion 54 is electrically highly resistant because it is oxidized. Thus, the current flowing in the light-emitting unit 50 can be concentrated in the center of the light-emitting unit 50, and the light-emitting efficiency can be increased. The current that has flown through the lower DBR layer 51 flows into the lower electrode 62 and returns to the laser driver side. The lower electrode 62 is formed on the first principal plane 41A of the semiconductor substrate 40. Therefore, the current flowing in the light-emitting unit 50 does not flow in the semiconductor substrate 40, or only a very small current flows in the semiconductor substrate 40.

### Method of Producing Semiconductor Laser Device

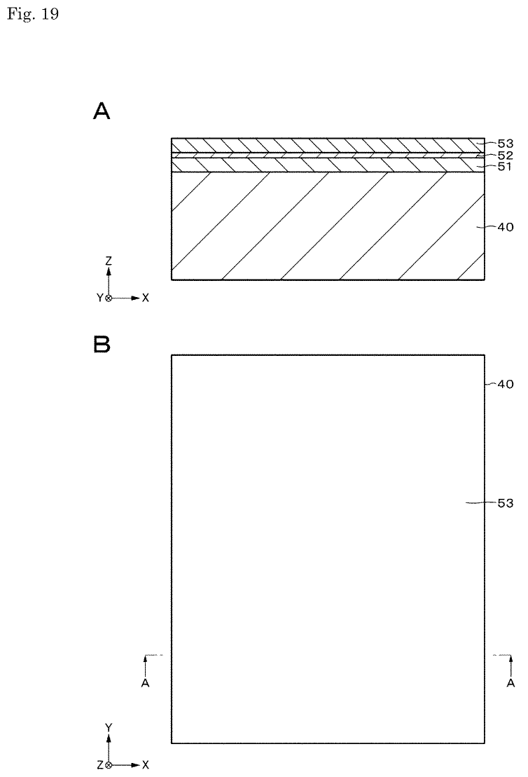

Next, an example of a method for producing the semiconductor laser device 100 described above will be explained with reference to FIGS. 19 to 23. In FIGS. 19 to 23, the lower views are the top views of the semiconductor laser device 100, and the upper views are the sectional views illustrating the sections of the lower views cut along the cutting lines A-A.

As illustrated in FIGS. 19A and 19B, crystals are grown on the first principal plane 41A of the semiconductor substrate 40 for forming a stacked structure of the light-emitting unit 50. For example, crystals are grown (epitaxially grown) to form, from the bottom, the lower DBR layer 51, an easily oxidizable layer (not illustrated), the active layer 52, and the upper DBR layer 53.

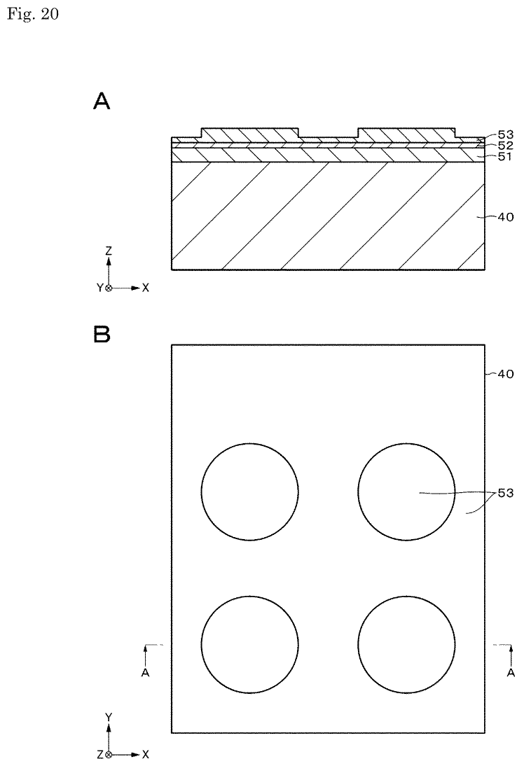

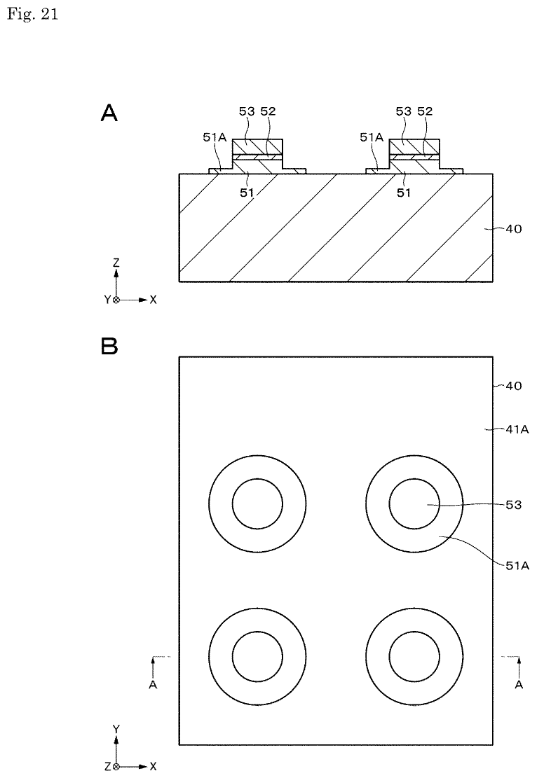

After that, as illustrated in each of FIGS. 20A and 20B or FIGS. 21A and 21B, a layer on which crystals have been grown is etched by two-stage etching to form the desired shape. This provides a shape in which the lower DBR layer 51 has a wide portion 51A.

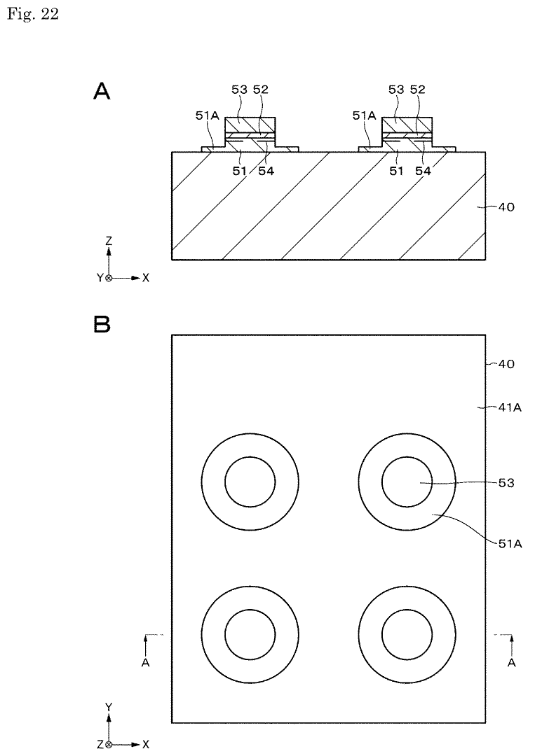

Subsequently, as illustrated in FIGS. 22A and 22B, an oxidized constriction portion 54 that is a region where the oxidation has progressed is formed by water vapor oxidation to the easily oxidizable layer formed during the crystal growth.

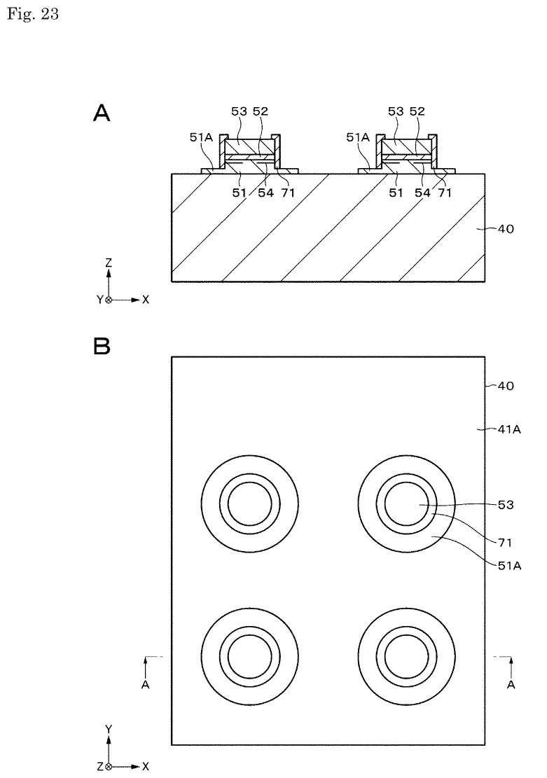

Next, as FIGS. 23A and 23B, the first protective film 71, which is an insulating body, is formed over the upper peripheral surface of the lower DBR layer 51, the peripheral surface of the active layer 52, and the peripheral surface of the upper DBR layer 53 (which may be a part of the upper part). For example, the first protective film 71 can be formed by a method for preparing the desired shape by depositing a protective film over the entire surface and performing etching.

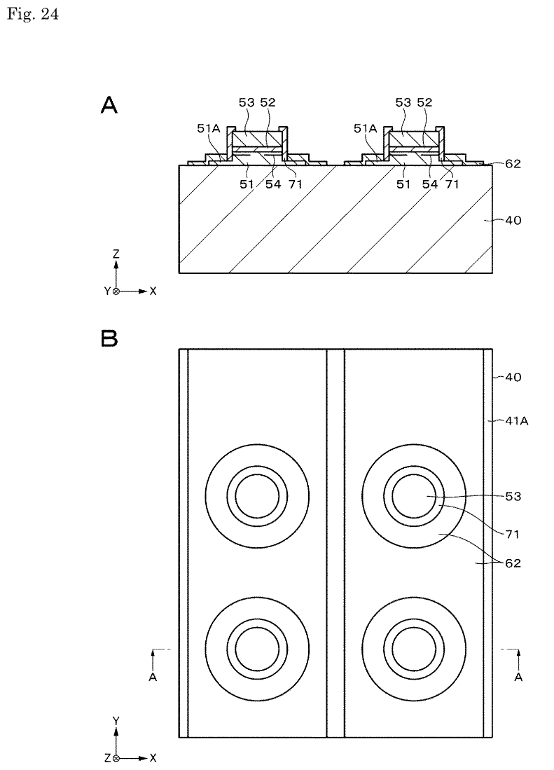

After that, the lower electrode 62 is formed, as illustrated in FIGS. 24A and 24B. For example, the lower electrode 62 is formed so as to be in contact with the wide portion 51A. For example, the lower electrode 62 may be formed by a film deposition technique called lift-off.

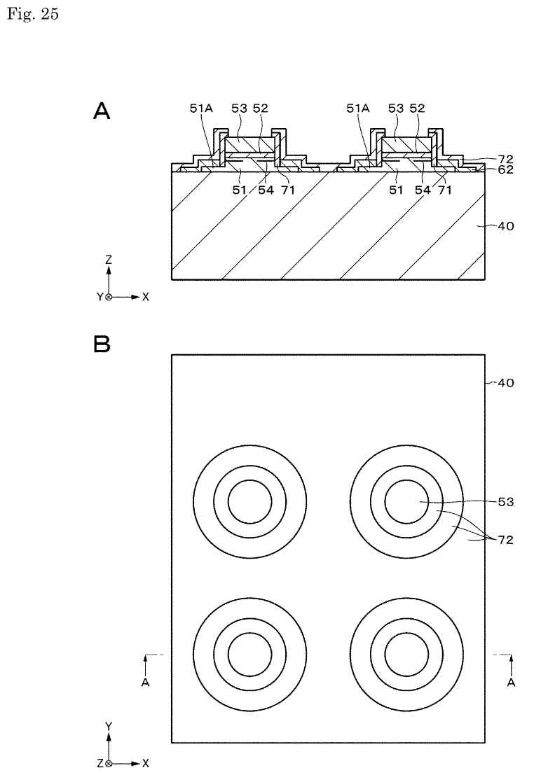

Subsequently, a second protective film 72, which is an insulating body, is formed, as illustrated in FIGS. 25A and 25B. For example, the second protective film 72 can be formed by a method for preparing the desired shape by depositing a protective film over the entire surface and performing etching.

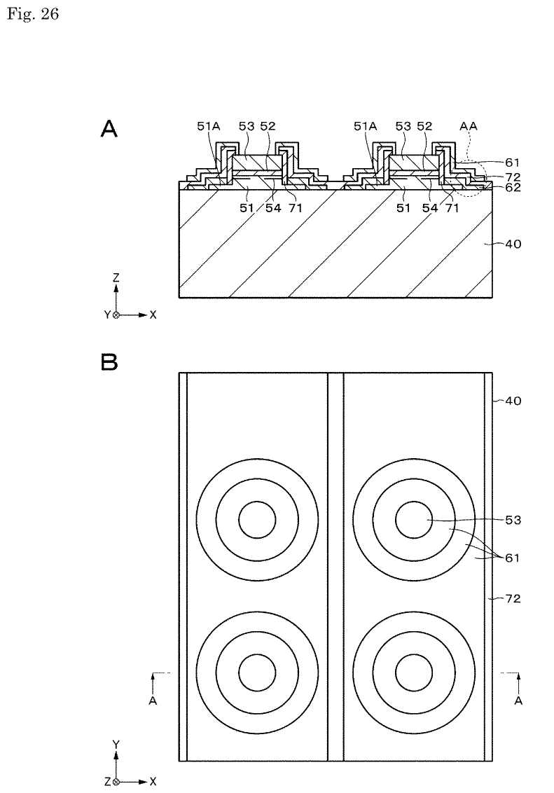

Next, the upper electrode 61 is formed, as illustrated in FIGS. 26A and 26B. The upper electrode 61 is formed to be in contact with an upper DBR layer 53. For example, the upper electrode 61 may be formed by a film deposition technique called lift-off.

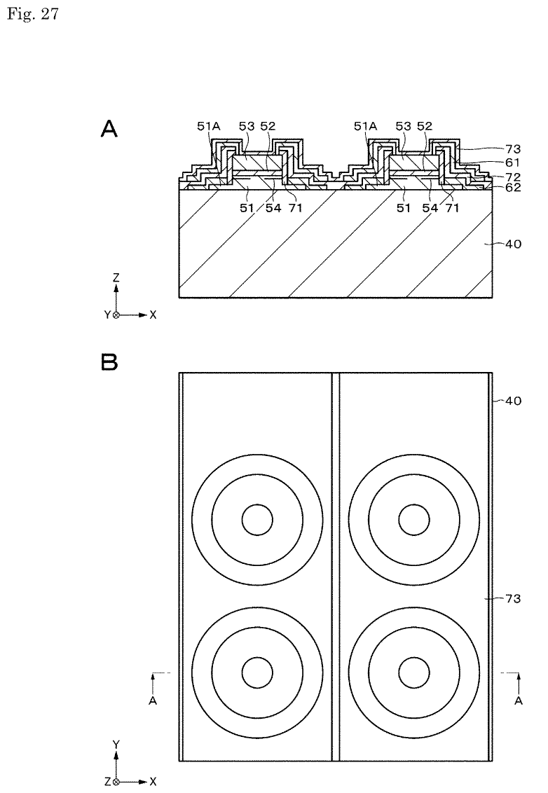

Finally, a third protective film 73, which is an insulating body, is formed, as illustrated in FIGS. 27A and 27B. For example, the third protective film 73 can be formed by a method for preparing the desired shape by depositing a protective film over the entire surface and performing etching. The semiconductor laser device 100 is thus produced in the manner stated above.

### Effect Obtained by Present Embodiment

According to the present embodiment, for example, the following effects can be obtained.

When a current is injected from the exterior of the semiconductor laser device, opposite currents flow to the upper and lower electrodes, respectively, and the inductance can thereby be reduced.

Furthermore, the inductance can be greatly reduced because the upper electrode and the lower electrode are stacked via a second protective film, and the second protective film is thin. This allows the inductance between the upper electrode and the lower electrode to be very small.

Since the inductance can be made very small, a rapid response speed of the light-emitting unit can be realized when the semiconductor laser device is driven. That is, the variation in light-emitting timings among a plurality of light-emitting units is eliminated as much as possible, and the transient response characteristics of laser beams are increased. Furthermore, when the semiconductor laser device is used as a light source of a distance measurement device, distance measurement accuracy can be increased. Furthermore, in the present embodiment, the contact area between the lower DBR layer and the lower electrode can be increased compared to the constitution without any wide portion (compared to a constitution where the width is constant), and the current can easily flow into the lower electrode by forming the wide portion in the lower DBR layer. Furthermore, the lower electrode can be wider by forming a wide portion, and, therefore, the electric resistance of the lower electrode can be reduced. When an n-type substrate is used as a semiconductor substrate, a contact can be made by bringing the electrode into contact with the substrate. Meanwhile, when a semi-insulating substrate is used as a semiconductor substrate, it is difficult to make a contact by bringing the electrode into contact with the substrate, and it is also difficult to increase the contact area between the lower electrode and the lower DBR layer. However, the contact area between the lower DBR layer and the lower electrode can be increased by forming a wide portion, and, therefore, such inconvenience can be avoided.

Furthermore, the inductance can be effectively reduced when the currents flowing in each are opposite to each other by shaping the external shapes of the upper electrode and the lower electrode to be substantially the same shape. Here, the external shapes of the upper electrode and the lower electrode mean the shapes of the semiconductor substrate 40 in the in-plane direction (the X direction in the present embodiment). In the present embodiment, the external shape means a shape that becomes wider in the X direction and has steps (for example, the shape of the area with the reference symbol AA in FIG. 26).

### Second Embodiment

Next, a second embodiment will be described. In the explanation of the second embodiment, the same reference numerals and symbols are assigned to the same or homogeneous components as the above-described components, and repeated explanations will be appropriately omitted. The matters described in the first embodiment can be applied to the second embodiment unless otherwise mentioned.

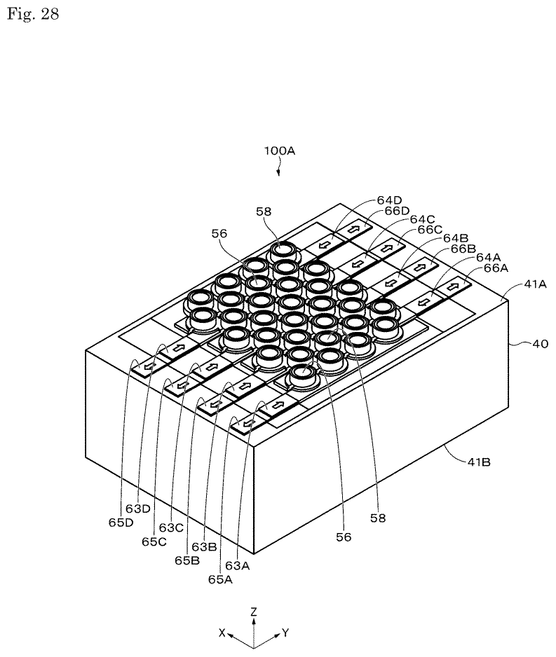

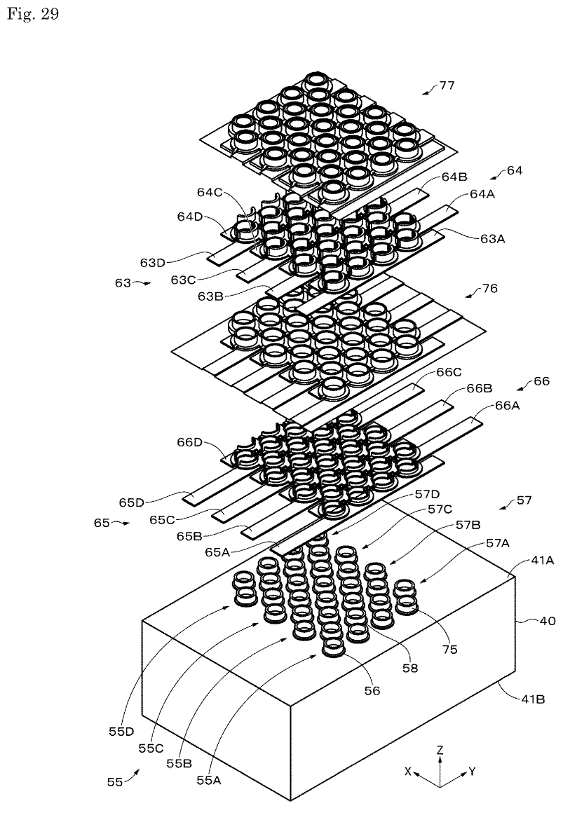

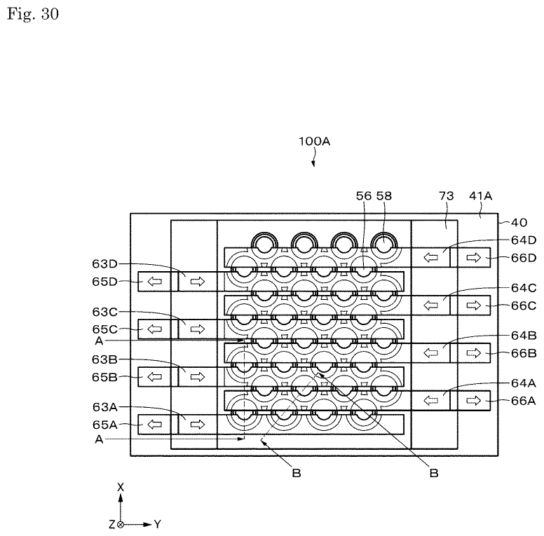

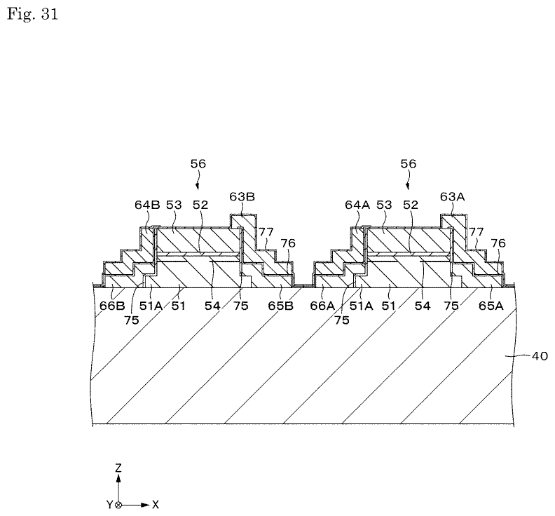

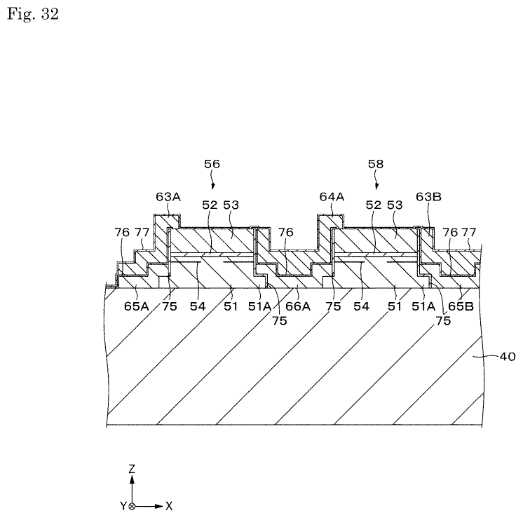

Hereafter, a semiconductor laser device (semiconductor laser device 100A) according to the present embodiment is explained with reference to FIGS. 28 to 32. FIG. 28 is a perspective view of the semiconductor laser device 100A. FIG. 29 is an exploded perspective view of the semiconductor laser device 100A. FIG. 30 is a top view of the semiconductor laser device 100A. FIG. 31 is an edge view when the semiconductor laser device 100A is cut along the cutting line A-A in FIG. 30. FIG. 32 is an edge view when the semiconductor laser device 100A is cut along the cutting line B-B in FIG. 30.

The semiconductor laser device 100A schematically has a semiconductor substrate 40, a plurality of light-emitting units, an upper electrode, a lower electrode, a fourth protective film 75, a fifth protective film 76, and a sixth protective film 77. The upper electrode according to the present embodiment includes an upper electrode 63 (one example of the first electrode according to the present embodiment) and an upper electrode 64 (one example of the third electrode according to the present embodiment). The lower electrode according to the present embodiment includes a lower electrode 65 (one example of the second electrode according to the present embodiment) and a lower electrode 66 (one example of the fourth electrode according to the present embodiment). For example, the upper electrode 63 includes upper electrodes 63A to 63D, which are separated from one another. For example, the upper electrode 64 includes upper electrodes 64A to 64D, which are separated from one another. For example, the lower electrode 65 includes lower electrodes 65A to 65D, which are separated from one another. For example, the lower electrode 66 includes lower electrodes 66A to 66D, which are separated from one another.

On the first principal plane 41A of the semiconductor substrate 40, a first light-emitting unit array 55 and a second light-emitting unit array 57 are formed. The first light-emitting unit array 55 has a light-emitting unit array consisting of four light-emitting unit 56 (one example of the first light-emitting unit) extending in the Y direction. Specifically, the first light-emitting unit array 55 has light-emitting unit arrays 55A, 55B, 55C, and 55D. The second light-emitting unit array 57 has a light-emitting unit array consisting of four light-emitting unit 58 (one example of the second light-emitting unit) extending in the Y direction. Specifically, the second light-emitting unit array 57 has light-emitting unit arrays 57A, 57B, 57C, and 57D. The light-emitting unit array of the first light-emitting unit array 55 and the light-emitting unit array of the second light-emitting unit array 57 are alternately formed. For example, a light-emitting unit array 57A is formed so as to be adjacent to the light-emitting unit array 55A, and the light-emitting unit array 55B is formed so as to be adjacent to the light-emitting unit array 57A. The number of the light-emitting units in the light-emitting unit array and the arrangement form of the light-emitting units are changeable, as appropriate, by all means. As the constitutions of the light-emitting unit 56 and light-emitting unit 58, the constitution of the light-emitting unit 50 explained in the first embodiment may be applied. The constitution of the light-emitting unit 56 may differ from the constitution of the light-emitting unit 58. As one example, the light-emitting unit 56 is used as a light-emitting unit for uniform irradiation in the related techniques described above, and the light-emitting unit 58 is used as a light-emitting unit for spot irradiation in the related techniques described above.

As illustrated in FIG. 29, with respect to the light-emitting units 56 and 58, the lower electrodes 65 and 66, the fifth protective film 76, the upper electrodes 63 and 64, and the sixth protective film 77 are arranged to be stacked in this order.

A fourth protective film 75 is formed on the side surfaces of each of the light-emitting unit 56 and the light-emitting unit 58. For example, when the section of the light-emitting unit 56 is viewed from the Y direction, the fourth protective film 75 is formed in a half (for example, right half) of the peripheral surface such that a part (for example, the peripheral surface of the wide portion 51A) of the lower DBR layer 51 be exposed, and the fourth protective film 75 is formed over the entire surface of the other half (for example, left half) of the peripheral surface (see FIG. 31). Meanwhile, when the section of the light-emitting unit 58 is viewed from the same direction (the Y direction in this example), the fourth protective film 75 is formed in a half (for example, right half) of the peripheral surface such that a part (for example, the peripheral surface of the wide portion 51A) of the lower DBR layer 51 be exposed, and the fourth protective film 75 is formed over the entire surface of the other half (for example, left half) of the peripheral surface (see FIG. 32; provided that FIG. 32 is a diagram viewed from the opposite side of FIG. 31).

As illustrated in FIG. 31, the upper electrode 63 (the upper electrodes 63A and 63B in the illustrated example) is electrically connected to the upper DBR layer 53 of the light-emitting unit 56 when the section is viewed from the Y direction. Here, since the fourth protective film 75 is formed on the peripheral surface of the upper DBR layer 53, the upper electrode 63 is formed to be connected to the upper side of the upper DBR layer 53. The lower electrode 65 (the upper electrodes 65A and 65B in the illustrated example) is electrically connected to the lower DBR layer 51 of the light-emitting unit 56 when the section is viewed from the Y direction. Here, the fourth protective film 75 is not formed on the peripheral surface of the wide portion 51A of the lower DBR layer 51. Then, the lower electrode 65 is formed so as to be connected to the surface of the wide portion 51A.

Meanwhile, as illustrated in FIGS. 31 and 32, the upper electrode 64 is not electrically connected to the light-emitting unit 56. For example, the upper electrode 64 is formed such that the upper edge thereof on the light-emitting unit 56 side in the Z direction is in substantially the same position as or below the upper edge of the light-emitting unit 56 side in the Z direction.

Furthermore, a fourth protective film 75 is formed over the entire surface of the peripheral surface (for example, the left side peripheral surface) on the upper electrode 64 side of the light-emitting unit 56. This means that the upper electrode 64 is not electrically connected to the light-emitting unit 56. Furthermore, the fourth protective film 75 is formed over the entire surface of the peripheral surface (for example, the left side peripheral surface) of the light-emitting unit 56 on the lower electrode 66 side, including the wide portion 51A; therefore, the lower electrode 66 is also not electrically connected to the light-emitting unit 56. That is, since the fourth protective film 75 is formed between the upper electrode 64 or the lower electrode 66 and the light-emitting unit 56, these electrodes are not electrically connected to the light-emitting unit 56.

As illustrated in FIG. 32, the upper electrode 64 (the upper electrode 64A in the illustrated example) is electrically connected to the upper DBR layer 53 of the light-emitting unit 58 (an example of the third region). Here, since the fourth protective film 75 is formed on the peripheral surface of the upper DBR layer 53, the upper electrode 64 is formed so as to be connected to the upper side of the upper DBR layer 53. The lower electrode 66 (the lower electrode 66A in the illustrated example) is electrically connected to the lower DBR layer 51 of the light-emitting unit 56. Here, the fourth protective film 75 is not formed on the peripheral surface of the wide portion 51A in the lower DBR layer 51 (an example of the fourth region) of the light-emitting unit 58. Then, the lower electrode 66 is formed so as to be electrically connected to the surface of the wide portion 51A of the light-emitting unit 58.

As illustrated in FIGS. 31 and 32, the upper electrode 63 is not electrically connected to the light-emitting unit 58. For example, the upper electrode 63 is formed such that the upper edge thereof on the light-emitting unit 58 side in the Z direction is in substantially the same position as or below the upper edge of the light-emitting unit 58 side in the Z direction. Furthermore, a fourth protective film 75 is formed over the entire surface of the peripheral surface (for example, the left side peripheral surface) of the light-emitting unit 58 on the upper electrode 63 side. This means that the upper electrode 63 is not electrically connected to the light-emitting unit 58. Furthermore, the fourth protective film 75 is formed over the entire surface of the peripheral surface (for example, left side peripheral surface) on the upper electrode 63 side of the light-emitting unit 58, including the wide portion 51A; therefore, the lower electrode 65 is also not electrically connected to the light-emitting unit 58. That is, since the fourth protective film 75 is formed between the upper electrode 63 or the lower electrode 65 and the light-emitting unit 58, these electrodes are not electrically connected to the light-emitting unit 58.

As the materials for the upper electrodes 63 and 64 and the lower electrodes 65 and 66, materials similar to those for the upper electrode 61 and the lower electrode 62 can be applied. As the materials for the fourth protective film 75, the fifth protective film 76, and the sixth protective film 77, materials similar to those for the first protective film 71, the second protective film 72, and the like can be applied.

As illustrated in FIG. 28, the edges of the upper electrode 63 and the lower electrode 65 extend to the vicinity of the periphery of the semiconductor substrate 40. The edge of the lower electrode 65 extends closer to the periphery of the semiconductor substrate 40 than the edge of the upper electrode 63. Similarly, the edges of the upper electrode 64 and the lower electrode 66 extend to the vicinity of the periphery of the semiconductor substrate 40. The edge of the lower electrode 66 extends closer to the periphery of the semiconductor substrate 40 than the edge of the upper electrode 64.

The upper electrode 63 is connected, for example, by wire bonding, to an anode electrode connected to a laser driver (all not illustrated). The lower electrode 65 is connected, for example, by wire bonding, to a cathode electrode connected to a laser driver (all not illustrated). The upper electrode 64 is connected, for example, by wire bonding, to an anode electrode connected to a laser driver (a laser driver different from the laser driver to which the upper electrode 63 is connected) (all not illustrated). The lower electrode 66 is connected, for example, by wire bonding, to a cathode electrode connected to a non-illustrated laser driver (a laser driver different from the laser driver to which the lower electrode 65 is connected) (all not illustrated).

### Operation of Semiconductor Laser Device

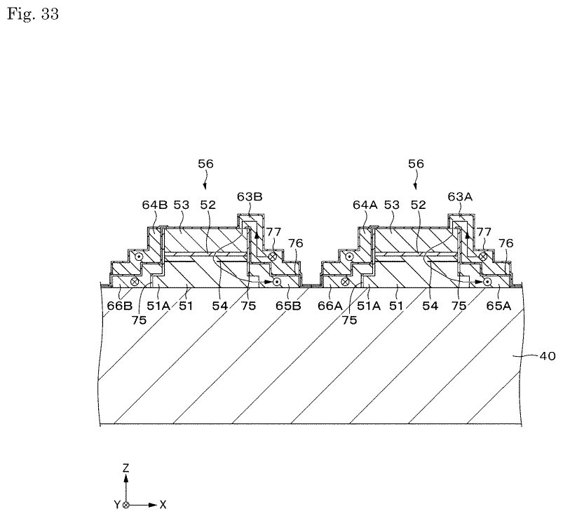

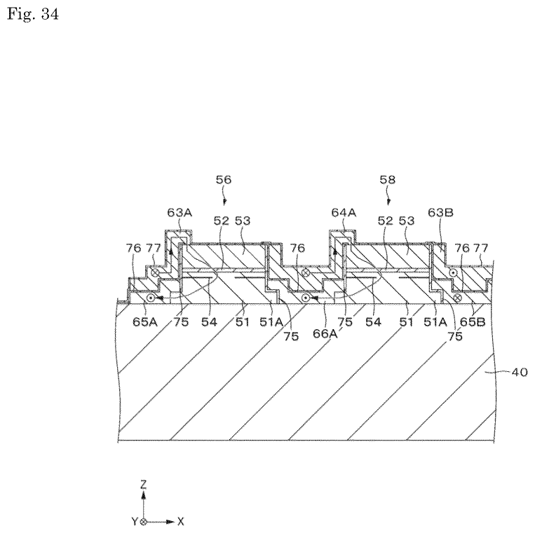

Next, the operation of the semiconductor laser device 100A according to the present embodiment will be described with reference to FIGS. 33 and 34. In FIGS. 33 and 34, the direction and flow of currents are indicated by arrows.

As illustrated in FIGS. 33 and 34, the direction of current flowing in the upper electrode 63 is opposite to the direction of current flowing in the lower electrode 65. The direction of current flowing in the upper electrode 64 is opposite to the direction of current flowing in the lower electrode 66. The direction of current flowing in the upper electrode 63 is opposite to the direction of current flowing in the upper electrode 64, and the direction of current flowing in the lower electrode 65 is opposite to the direction of current flowing in the lower electrode 66.

For example, a current is supplied to the semiconductor laser device 100A by a predetermined laser driver (not illustrated). As illustrated in FIG. 33, the supplied current flows in the upper electrode 63, passes through the upper DBR layer 53 of the light-emitting unit 56 and then through the active layer 52, and flows into the lower DBR layer 51. This allows the light-emitting unit 56 to emit light. Here, the oxidized constriction portion 54 is electrically highly resistant because it is oxidized. Thus, the current flowing in the light-emitting unit 56 can be concentrated in the center of the light-emitting unit 56, and the light-emitting efficiency can be increased. The current that has flown through the lower DBR layer 51 flows into the lower electrode 65 and returns to the predetermined laser driver side. The lower electrode 65 is formed on the first principal plane 41A of the semiconductor substrate 40. Therefore, the current flowing in the light-emitting unit 56 does not flow in the semiconductor substrate 40, or only a very small current flows in the semiconductor substrate 40. Furthermore, as illustrated in FIG. 34, the upper electrode 63 and the lower electrode 65 are not electrically connected to the light-emitting unit 58. Accordingly, when a current is allowed to flow in the upper electrode 63 and the lower electrode 65, the light-emitting unit 58 does not emit light.

A current is supplied to the semiconductor laser device 100A by another laser driver. As illustrated in FIG. 34, the supplied current flows in the upper electrode 64, passes through the upper DBR layer 53 of the light-emitting unit 58 and then through the active layer 52, and flows into the lower DBR layer 51. This allows the light-emitting unit 58 to emit a light beam. Here, the oxidized constriction portion 54 is electrically highly resistant because it is oxidized. Thus, the current flowing in the light-emitting unit 58 can be concentrated in the center of the light-emitting unit 58, and the light-emitting efficiency can be increased. The current that has flown through the lower DBR layer 51 flows into the lower electrode 66 and returns to another laser driver side. The lower electrode 66 is formed on the first principal plane 41A of the semiconductor substrate 40. Therefore, the current flowing in the light-emitting unit 58 does not flow in the semiconductor substrate 40, or only a very small current flows in the semiconductor substrate 40. Furthermore, as illustrated in FIG. 33, the upper electrode 64 and the lower electrode 66 are not electrically connected to the light-emitting unit 56. Accordingly, when a current is allowed to flow in the upper electrode 64 and the lower electrode 66, the light-emitting unit 56 does not emit light.

That is, when light is emitted from the light-emitting unit 56, control to allow current to flow to the upper electrode 63 and the lower electrode 65 can be performed. When light is emitted from the light-emitting unit 58, control to allow current to flow to the upper electrode 64 and the lower electrode 66 can be performed. This makes it possible to switch between the light emission from the light-emitting unit 56 and the light emission from the light-emitting unit 58 or to emit light at the same time from the light-emitting unit 56 and the light-emitting unit 58. For example, a microlens array that spotlights an object to be irradiated is placed on the optical path of the light emitted from the light-emitting unit 56, and a microlens array that uniformly irradiates an object to be irradiated with light is placed on the optical path of the light emitted from the light-emitting unit 58. By switching the light emission timing of the light-emitting unit 56 and light-emitting unit 58, it is possible to switch between spot irradiation and uniform irradiation of the object to be irradiated, or to irradiate the object to be irradiated with light for spot irradiation and light for uniform irradiation at the same time.

### Method for Producing Semiconductor Laser Device

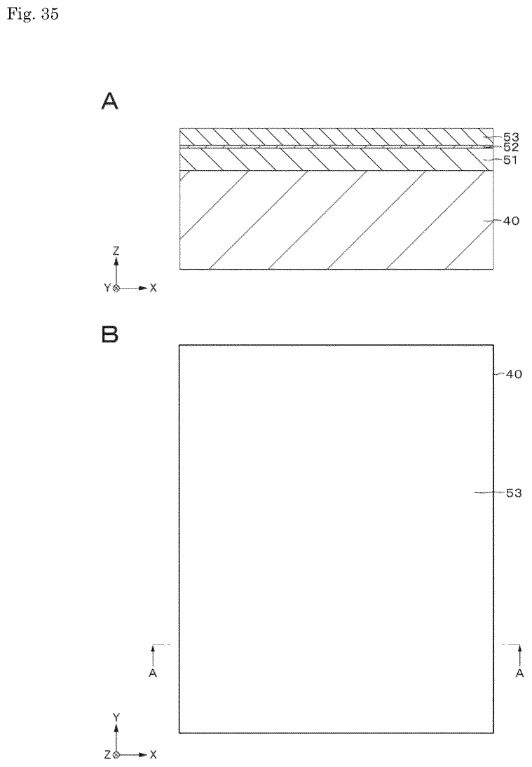

Next, an example of a method for producing the semiconductor laser device 100A described above will be explained with reference to FIGS. 35 to 43. In FIGS. 35 to 43, the lower views are the top views of the semiconductor laser device 100A, and the upper views are edge views illustrating the edge of the lower views cut along the cutting lines A-A.

As illustrated in FIGS. 35A and 35B, crystals are grown on the first principal plane 41A of the semiconductor substrate 40 for forming a stacked structure of the light-emitting unit 50. For example, crystals are grown (epitaxially grown) to form, from the bottom, the lower DBR layer 51, an easily oxidizable layer (not illustrated), the active layer 52, and the upper DBR layer 53.

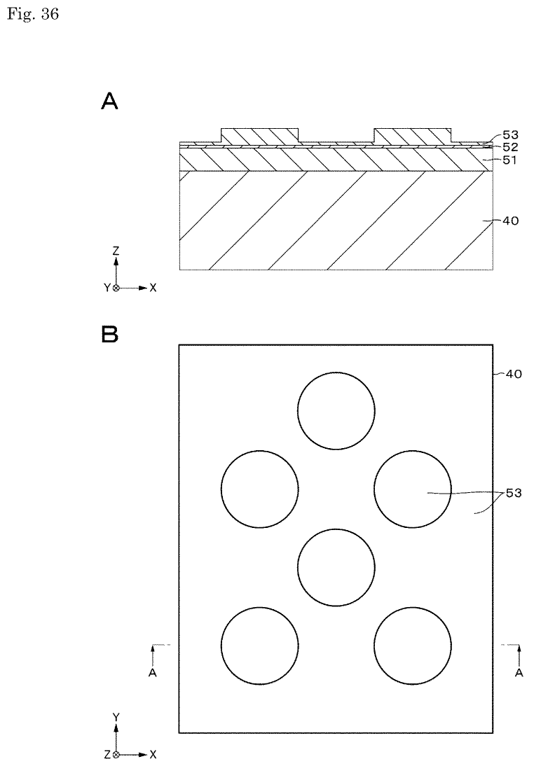

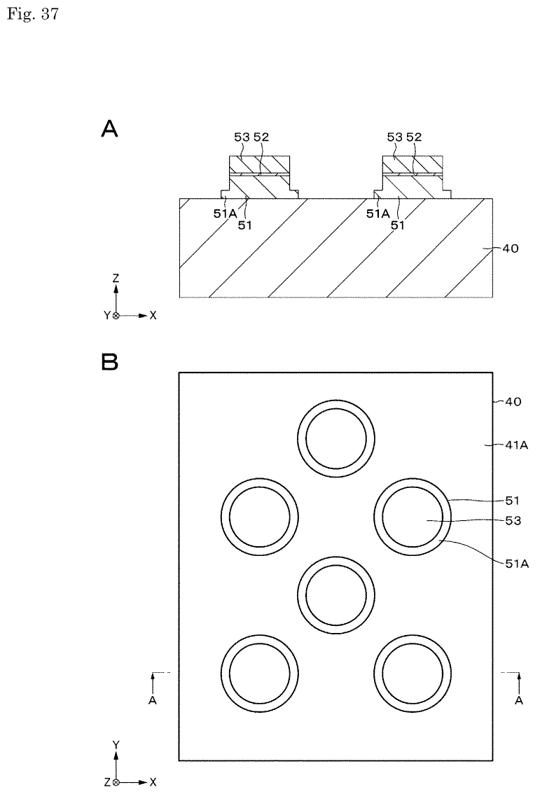

After that, as illustrated in each of FIGS. 36A and 36B or FIGS. 37A and 37B, a layer on which crystals have been grown is etched by two-stage etching to form the desired shape. A shape in which the lower DBR layer 51 has a wide portion 51A can be obtained.

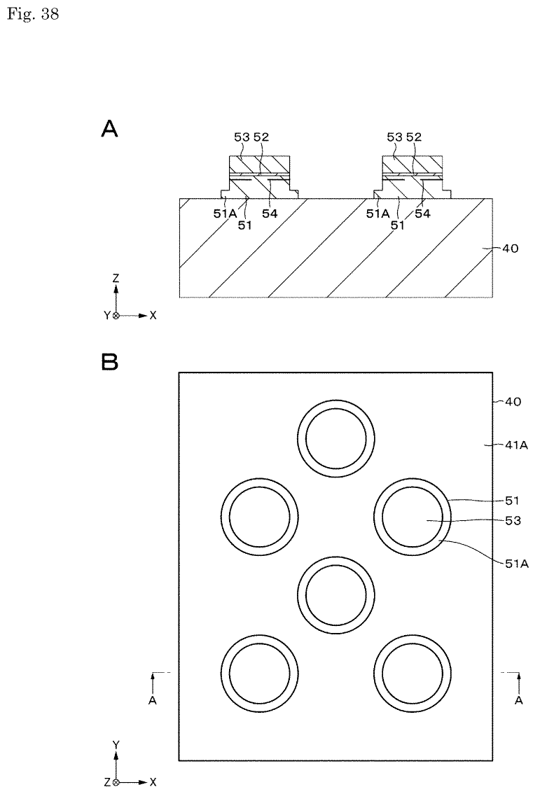

Subsequently, as illustrated in FIGS. 38A and 38B, an oxidized constriction portion 54 that is a region where the oxidation has progressed is formed by water vapor oxidation to the easily oxidizable layer formed during the crystal growth.

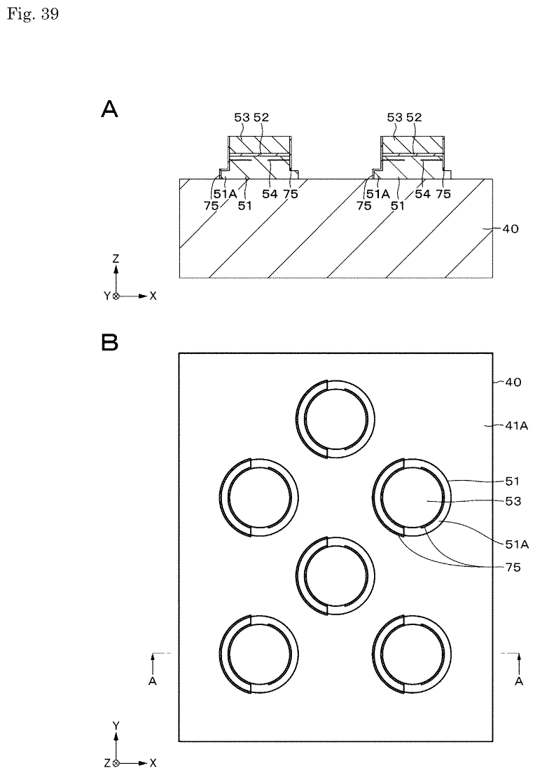

Next, as illustrated in FIGS. 39A and 39B, a fourth protective film 75 is formed to the stacked member (the stacked member of the lower DBR layer 51, the active layer 52, and the upper DBR layer 53) formed on the first principal plane 41A. For example, as illustrated in FIG. 39B, when the first principal plane 41A of the semiconductor substrate 40 is viewed from the top, the fourth protective film 75 is formed over the entire left side peripheral surface of the stacked member, including the wide portion 51A. On the right side peripheral surface of the stacked member, a fourth protective film 75 is formed, excluding the surface of the wide portion 51A. On the peripheral surface of the stacked member, the fourth protective film 75 may or may not be formed in areas not in contact with the upper electrode and the lower electrode.

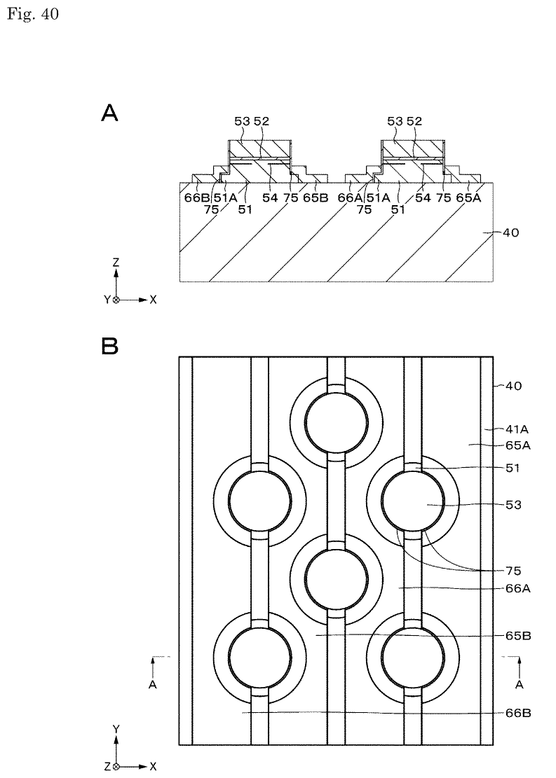

Next, as illustrated in FIGS. 40A and 40B, the lower electrode 65 and the lower electrode 66 are formed by the film deposition method, such as lift-off. At this time, as illustrated in FIG. 40A, the lower electrode 65 is formed on the right side of the stacked member corresponding to the light-emitting unit 56, and the lower electrode 66 is formed on the left side of the stacked member corresponding to the light-emitting unit 56. As described above, a region that is not covered with the fourth protective film 75 exists on the right side of the stacked member. Thus, as illustrated in FIG. 40A, the lower electrode 65 comes into contact with the lower DBR layer 51. Meanwhile, since the left side of the stacked member is covered with the fourth protective film 75, the lower electrode 66 is not in contact with the lower DBR layer 51. Although not illustrated, the lower electrode 66 is formed on the right side of the stacked member corresponding to the light-emitting unit 58, and the lower electrode 65 is formed on the left side of the stacked member corresponding to the light-emitting unit 58. As described above, a region that is not covered with the fourth protective film 75 exists on the right side of the stacked member. Thus, the lower electrode 66 comes into contact with the lower DBR layer 51. Meanwhile, since the left side of the stacked member is covered with the fourth protective film 75, the lower electrode 65 is not in contact with the lower DBR layer 51.

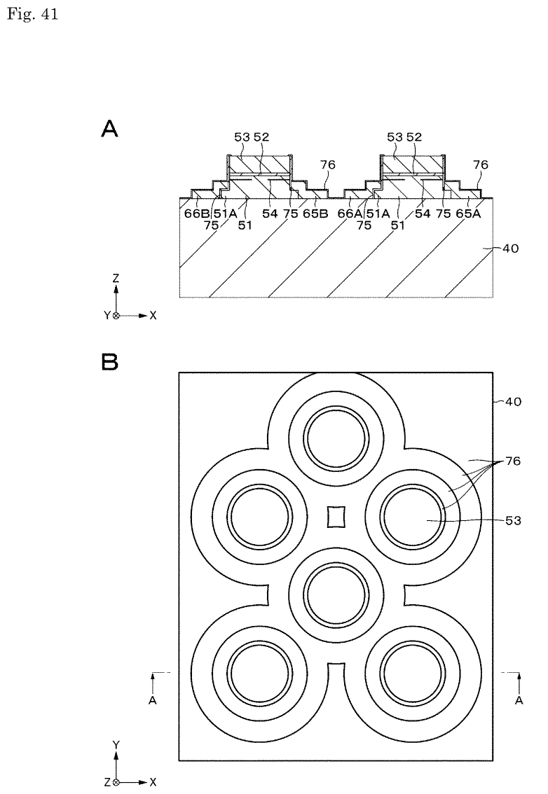

Next, a fifth protective film 76 is formed, as illustrated in FIGS. 41A and 41B. For example, the fifth protective film 76 can be formed by a method for preparing the desired shape by depositing a protective film over the entire surface and performing etching. The fifth protective film 76 is an insulating film that insulates between the upper electrode 63 and the lower electrode 65 and between the upper electrode 64 and the lower electrode 66.

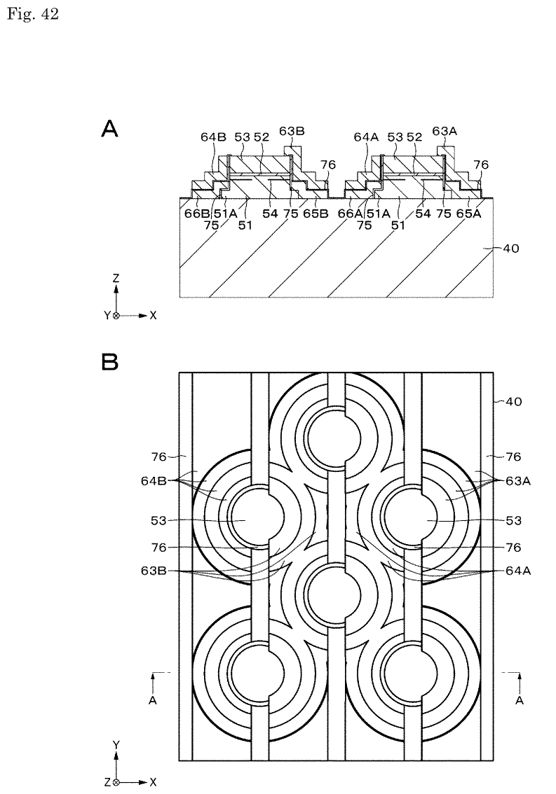

Next, as illustrated in FIGS. 42A and 42B, the upper electrode 63 and the upper electrode 64 are formed by a film deposition technique such as lift-off. At this time, the upper electrode 63 is formed to have a shape so as to come into contact with the upper DBR layer 53 (more specifically, the upper part of the upper DBR layer 53) in the stacked member corresponding to the light-emitting unit 56 but not to come into contact with the upper DBR layer 53 in the stacked member corresponding to the light-emitting unit 58. Furthermore, the upper electrode 64 is formed to have a shape so as to come into contact with the upper DBR layer 53 (more specifically, the upper part of the upper DBR layer 53) in the stacked member corresponding to the light-emitting unit 58 but not to come into contact with the upper DBR layer 53 in the stacked member corresponding to the light-emitting unit 56.

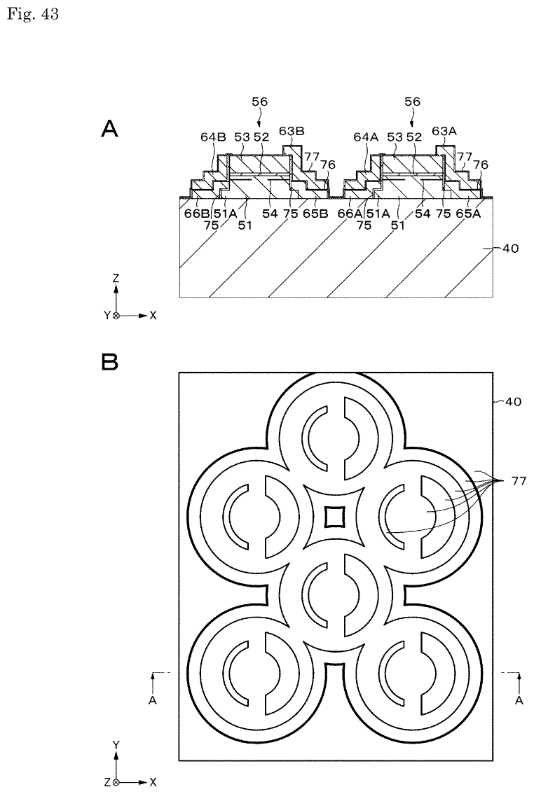

Finally, a sixth protective film 77, which is an insulating body, is formed, as illustrated in FIGS. 43A and 43B. For example, the sixth protective film 77 can be formed by a method for preparing the desired shape by depositing a protective film over the entire surface and performing etching. The semiconductor laser device 100A is thus produced in the manner stated above.

### Simulation Results

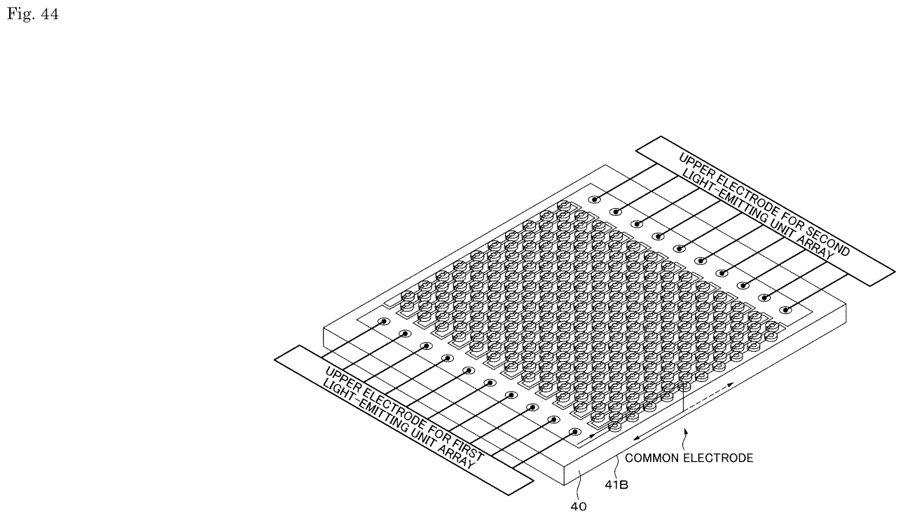

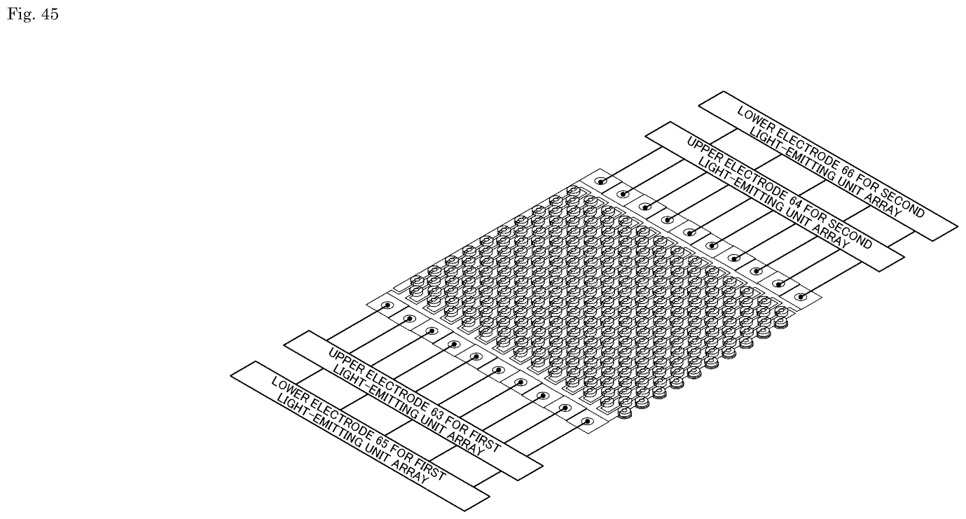

In order to confirm that the constitution according to the present embodiment can reduce the inductance, a simulation was performed using a computer. FIG. 44 illustrates a constitution according to a Comparative Example. In the constitution according to the Comparative Example, an upper electrode for the first light-emitting unit array and an upper electrode for the second light-emitting unit array were formed as with the present embodiment. The lower electrode was formed as a common electrode on the back surface (second principal plane 41B) of the semiconductor substrate 40, unlike the present embodiment. FIG. 45 illustrates a configuration according to an Example. As described above, the constitution according to the Example has the upper electrode 63 for the first light-emitting unit array, the lower electrode 65 for the first light-emitting unit array, the upper electrode 64 for the second light-emitting unit array, and the lower electrode 66 for the second light-emitting unit array. A common electrode is not formed on the back surface of the semiconductor substrate 40. In FIGS. 44 and 45, the illustration is simplified by appropriately omitting the illustration of protective films or the like.

The number of light-emitting units (light-emitting units 56) constituting the first light-emitting unit array and the number of light-emitting units (light-emitting units 58) constituting the second light-emitting unit array were each set to 300 (600 in total). Au was used as the material for the upper electrode and the lower electrode. The thickness of the semiconductor substrate 40 was set to 100 μm.

In the Comparative Example, for example, when a driving signal is provided to the upper electrode, a current flows in the light-emitting unit in the first light-emitting unit array, and the current flows toward the lower electrode formed on the back surface of the semiconductor substrate 40. The current that has flown through the lower electrode flows toward the edge of the semiconductor substrate 40, as indicated by the arrow in FIG. 44. Since the semiconductor substrate 40 has a thickness, the cancellation of magnetic fields by the current flowing in the upper electrode and the current flowing in the lower electrode is weak, and inductance cannot be decreased. Furthermore, the current that has flown through the lower electrode also flows in the direction indicated by the dotted arrow, which may induce an increase in inductance. As a result of computer simulation, the inductances were 55 pH, which was a relatively large value, both in the current path flowing from the upper electrode toward the lower electrode in the first light-emitting unit array and the current path flowing from the upper electrode toward the lower electrode in the second light-emitting unit array.

In contrast, in the Example, when a driving signal is provided to the upper electrode 63, a current flows in the light-emitting unit 56 constituting the first light-emitting unit array, and thereafter, a current flows in the lower electrode 65, as illustrated in FIG. 45. When a driving signal is provided to the upper electrode 64, a current flows in the light-emitting unit 58 constituting the second light-emitting unit array, and thereafter, a current flows in the lower electrode 66. If the semiconductor substrate (not illustrated in FIG. 45) is a semi-insulating substrate, the current path (current path A) flowing from the upper electrode 63 to the lower electrode 65 and the current path (current path B) flowing from the upper electrode 64 to the lower electrode 66 are electrically separated as such.

As a result of the calculation for the inductance in these current paths by computer simulation, the inductances in the current path A and the current path B were both 5 pH. That is, the inductances were very small values and were −50 pH (about 90% reduction) from the value of Comparative Example 1. This is because the magnetic fields are canceled by the current flowing in the upper electrode 63 and the current flowing in the lower electrode 65, and the magnetic fields are canceled by the current flowing in the upper electrode 64 and the current flowing in the lower electrode 66. The upper electrode 63 and the lower electrode 65 are stacked in the thickness direction via a thin protective film (a fifth protective film 76 (not illustrated)), and the upper electrode 64 and the lower electrode 66 are stacked in the thickness direction via a thin protective film (a fifth protective film 76 (not illustrated)), and this allows the inductance to be reduced due to the strong magnetic field cancellation.

The present Example is an example using a semi-insulating substrate as a semiconductor substrate. This can electrically separate the current path A and the current path B. If an n-type or p-type substrate is applied as a semiconductor substrate, the current path A and the current path B cannot be completely separated electrically, and a leak current may occur. However, since this current leakage is not so large, a certain effect can be exhibited even if it is not a semi-insulating substrate.

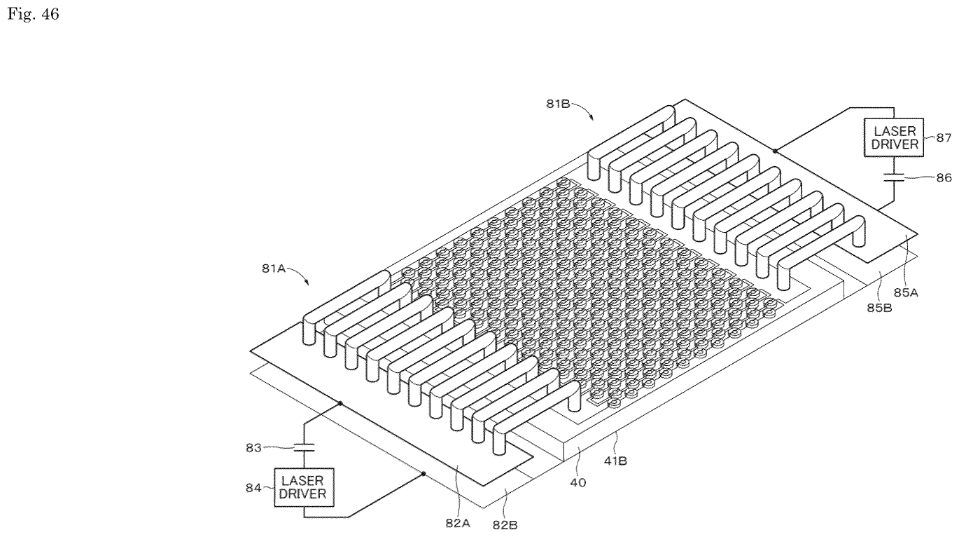

FIG. 46 is a modularized configuration of the configuration illustrated in FIG. 44. The upper electrode connected to the first light-emitting unit array is connected to the upper electrode 82A on the laser driver side via a wire bonding connection 81A. The lower electrode formed on the second principal plane 41B of the semiconductor substrate 40 is connected to the lower electrode 82B on the laser driver side. The upper electrode 82A on the laser driver side is connected to a laser driver 84 via a bypass capacitor 83. The lower electrode 82B on the laser driver side is connected to a laser driver 84.

The upper electrode connected to the second light-emitting unit array is connected to an upper electrode 85A on the laser driver side via a wire bonding connection 81B. The lower electrode formed on the second principal plane 41B of the semiconductor substrate 40 is connected to a lower electrode 85B on the laser driver side. The upper electrode 85A on the laser driver side is connected to the laser driver 87. The lower electrode 85B on the laser driver side is connected to the laser driver 87 via a bypass capacitor 86.

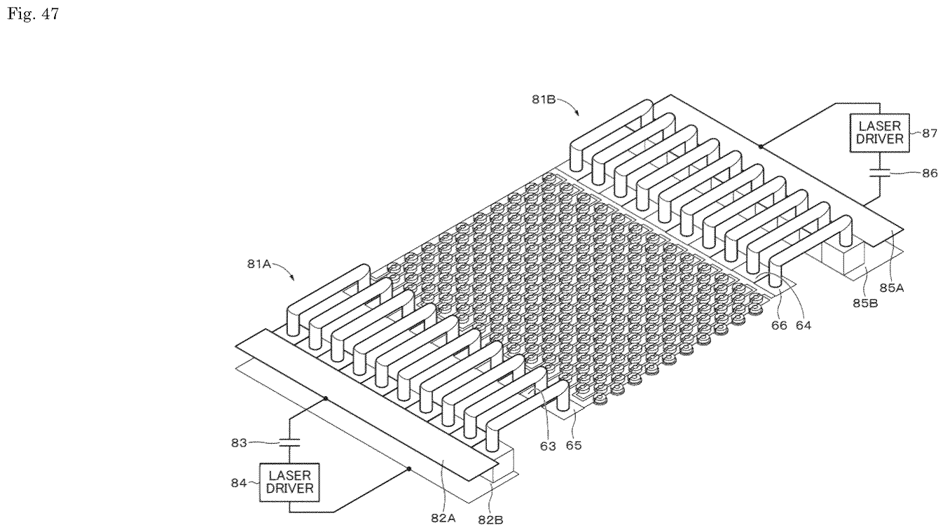

FIG. 47 is a modularized configuration of the configuration illustrated in FIG. 45. The upper electrode 63 is connected to an upper electrode 82A on the laser driver side via a wire bonding connection 81A. The lower electrode 65 is connected to a lower electrode 82B on the laser driver side via the wire bonding connection 81A. The upper electrode 82A on the laser driver side is connected to a laser driver 84 via a bypass capacitor 83. The lower electrode 82B on the laser driver side is connected to the laser driver 84. The upper electrode 64 is connected to the upper electrode 85A on the laser driver side via the wire bonding connection 81B. The lower electrode 66 is connected to the lower electrode 85B on the laser driver side via the wire bonding connection 81B. The upper electrode 85A on the laser driver side is connected to a laser driver 87. The lower electrode 85B on the laser driver side is connected to the laser driver 87 via a bypass capacitor 86.

The values of inductances were simulated on each of the modularized Comparative Example and Example by a computer simulation. As the results of the simulation, the inductances of the Comparative Example were 250 pH both in the path of the current flowing in the first light-emitting unit array and the path of the current flowing for the second light-emitting unit array. In contrast, the inductances in the Example were 120 pH both in the current path A and the current path B. That is, even when the semiconductor laser device is modularized, the inductance could be reduced in Example 1 to −130 pH (about 50% reduction) from the value of Comparative Example 1.

### Modification Examples

Although embodiments of the present disclosure have been described above in detail, the content of the present disclosure is not limited to the above-described embodiments, and various modifications based on the technical spirit of the present disclosure can be made.

For example, in the first embodiment described above, a plurality of array structures including the light-emitting units and the upper and the lower electrodes electrically connected to the light-emitting units may be formed on the first principal plane. The driving timing for an individual array structure may be any timing.

The present disclosure can be realized not only in the form of a semiconductor laser device, but also in the form of a distance measurement device using the semiconductor laser device, a vehicle-mounted device having the distance measurement device, a method, and the like. The effects described in the present description are merely examples and are not intended as limiting, and other effects may be obtained.

The present disclosure can also be configured as follows.
(1)

A semiconductor device including:
a semiconductor substrate having a first principal plane and a second principal plane opposite to the first principal plane,
a plurality of light-emitting units disposed on the first principal plane,
a first electrode electrically connected to a first region that is one region when an active region of each of the light-emitting unit serves as a boundary, and
a second electrode electrically connected to a second region that is the other region when the active region of each of the light-emitting unit serves as the boundary,
wherein
the first electrode and the second electrode are stacked via an insulating film therebetween on the first principal plane along a thickness direction of the semiconductor substrate.
(2)

The semiconductor laser device according to (1), wherein
each of the light-emitting unit has a structure protruding with respect to the first principal plane, and
the first region is an upper side region, and the second region is a lower side region including a part in contact with the first principal plane.
(3)

The semiconductor laser device according to (2), wherein
when the light-emitting unit is viewed in a cross-section, the second region has a wide portion where a part in contact with the first principal plane is wide, and
the second electrode is electrically connected to the wide portion.
(4)

The semiconductor laser device according to (1) to (3), wherein
the first electrode and the second electrode are arranged along a substantially identical direction in the plane of the first principal plane.
(5)

The semiconductor laser device according to (1) to (4), wherein
a direction of a current flowing in the first electrode and a direction of a current flowing in the second electrode are opposite.
(6)

The semiconductor laser device according to (1) to (5), wherein
an outer shape of the first electrode and an outer shape of the second electrode are substantially identical.
(7)

The semiconductor laser device according to (1) to (6), further including:
a third electrode and a fourth electrode, wherein
a plurality of first light-emitting units and a plurality of second light-emitting units are disposed on the first principal plane,
the first electrode is electrically connected to a first region that is one region when an active region of each of the first light-emitting unit serves as a boundary,
the second electrode is electrically connected to a second region that is the other region when the active region of each of the first light-emitting unit serves as the boundary,
the third electrode is electrically connected to a third region that is one region when an active region of each of the second light-emitting unit serves as a boundary,
the fourth electrode is electrically connected to a fourth region that is the other region when the active region of each of the second light-emitting unit serves as the boundary, and
the third electrode and the fourth electrode are stacked via an insulating film therebetween on the first principal plane along the thickness direction of the semiconductor substrate.
(8)

The semiconductor laser device according to (7), wherein
an insulating film is disposed between the third electrode and fourth electrode and the first light-emitting units.
(9)

The semiconductor laser device according to (7) or (8), wherein
a direction of a current flowing in the first electrode and a direction of a current flowing in the second electrode are opposite, and
a direction of a current flowing in the third electrode and a direction of a current flowing in the fourth electrode are opposite.
(10)

The semiconductor laser device according to (9), wherein
the direction of the current flowing in the first electrode and the direction of the current flowing in the third electrode are opposite, and
the direction of the current flowing in the second electrode and the direction of the current flowing in the fourth electrode are opposite.
(11)

The semiconductor laser device according to any of (7) to (10), wherein
the first electrode and the third electrode are not electrically connected, and the second electrode and the fourth electrode are not electrically connected.
(12)

The semiconductor laser device according to any of (1) to (11), wherein
the semiconductor substrate is a semi-insulating substrate.
(13)

The semiconductor laser device according to any of (1) to (12), wherein
a plurality of array structures including each of the light-emitting unit and the first electrode and second electrode electrically connected to the light-emitting unit are disposed on the first principal plane.
(14)

A distance measurement device including the semiconductor laser device according to any of (1) to (13).
(15)

A vehicle-mounted device including the distance measurement device according to (14).

### Application Examples

The technique according to the present disclosure can be applied to various products. For example, the technique according to the present disclosure may be implemented as an apparatus mounted on any kind of mobile body such as an automobile, an electric vehicle, a hybrid electric vehicle, a motorcycle, a bicycle, a personal mobility, an airplane, a drone, a ship, a robot, a construction machine, or an agricultural machine (tractor).

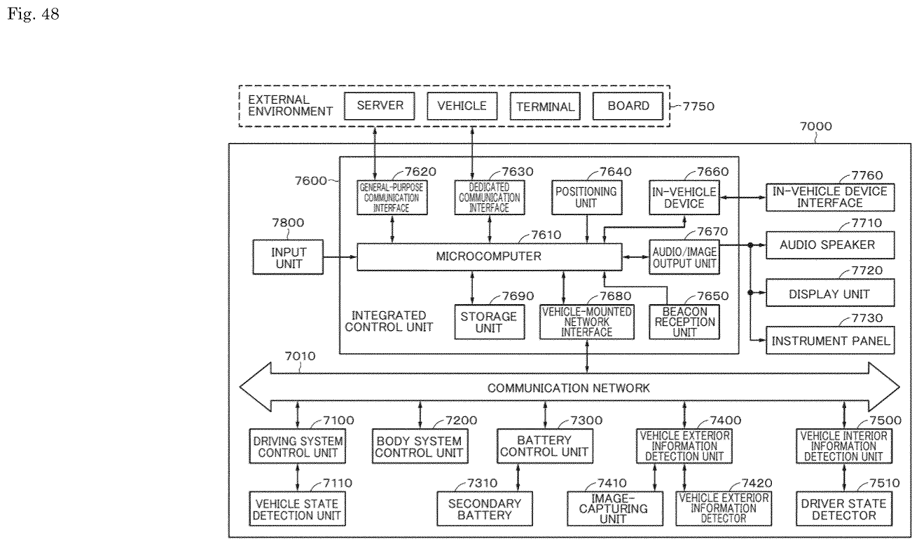

FIG. 48 is a block diagram illustrating a schematic configuration example of a vehicle control system 7000, which is an example of a mobile body control system to which the technique according to the present disclosure is applicable. The vehicle control system 7000 includes a plurality of electronic control units connected via a communication network 7010. In the example illustrated in FIG. 48, the vehicle control system 7000 includes a driving system control unit 7100, a body system control unit 7200, a battery control unit 7300, a vehicle exterior information detection unit 7400, a vehicle interior information detection unit 7500, and an integrated control unit 7600. The communication network 7010 connecting the plurality of control units may be, for example, an in-vehicle communication network compliant with any standards such as controller area network (CAN), local interconnect network (LIN), local area network (LAN), and FlexRay (registered trademark).

Each control unit includes a microcomputer that performs arithmetic processing according to various programs, a storage unit that stores programs executed by the microcomputer, parameters used for various arithmetic operations, and the like, and a drive circuit that drives various control target devices. Each control unit includes a network interface for performing communication with another control unit via the communication network 7010, and includes a communication interface for performing communication with devices or sensors inside or outside of the vehicle through wired communication or wireless communication. In FIG. 48, a microcomputer 7610, a general-purpose communication interface 7620, a dedicated communication interface 7630, a positioning unit 7640, a beacon reception unit 7650, an in-vehicle device interface 7660, an audio/image output unit 7670, a vehicle-mounted network interface 7680, and a storage unit 7690 are illustrated as functional configurations of the integrated control unit 7600. The other control units also include a microcomputer, a communication interface, a storage unit, and the like.

The driving system control unit 7100 controls the operations of devices related to the drive system of the vehicle according to various programs. For example, the driving system control unit 7100 functions as a control device for a driving force generation device for generating a vehicle driving force of an internal combustion engine or a driving motor, a driving force transmission mechanism for transmitting the driving force to wheels, a steering mechanism for adjusting a steering angle of the vehicle, a braking device that generates a braking force of the vehicle. The driving system control unit 7100 may have a function as a control device, for example, an antilock brake system (ABS) or electronic stability control (ESC).

A vehicle state detection unit 7110 is connected to the driving system control unit 7100. The vehicle state detection unit 7110 includes at least one of a gyro sensor that detects the angular velocity of an axial rotation motion of a vehicle body, an acceleration sensor that detects the acceleration of the vehicle, and sensors that detect the operation amount of an accelerator pedal, an operation amount of a brake pedal, a steering angle of a steering wheel, an engine speed, a rotation speed of wheels, and the like, for example. The driving system control unit 7100 performs arithmetic processing using a signal inputted from the vehicle state detection unit 7110 to control an internal combustion engine, a driving motor, an electric power steering device, a brake device, and the like.

The body system control unit 7200 controls the operations of various devices equipped in the vehicle body in accordance with various programs. For example, the body system control unit 7200 functions as a control device for a keyless entry system, a smart key system, a power window device, or various lamps such as a head lamp, a back lamp, a brake lamp, a turn indicator, and a fog lamp. In this case, radio waves emitted from a portable device as an alternative to keys or signals of various switches can be inputted to the body system control unit 7200. The body system control unit 7200 receives the input of radio waves or signals and controls a door lock device, a power window device, and a lamp of the vehicle.

The battery control unit 7300 controls a secondary battery 7310 which is a power supply source of a driving motor in accordance with various programs. For example, information such as a battery temperature, a battery output voltage, or the remaining capacity of a battery is inputted from a battery device including the secondary battery 7310 to the battery control unit 7300. The battery control unit 7300 performs arithmetic processing using such signals and performs temperature adjustment control of the secondary battery 7310 or control of a cooling device or the like equipped in the battery device.

The vehicle exterior information detection unit 7400 detects information outside of the vehicle in which the vehicle control system 7000 is mounted. For example, at least one of an image-capturing unit 7410 and a vehicle exterior information detector 7420 is connected to the vehicle exterior information detection unit 7400. The image-capturing unit 7410 includes at least one of a Time Of Flight (ToF) camera, a stereo camera, a monocular camera, an infrared camera, and other cameras. The vehicle exterior information detector 7420 includes at least one of, for example, an environmental sensor for detecting present weather or atmospheric phenomena and a surrounding information detection sensor for detecting other vehicles, obstacles, pedestrians, and the like around a vehicle on which the vehicle control system 7000 is mounted.

The environmental sensor may be, for example, at least one of a raindrop sensor that detects rainy weather, a fog sensor that detects fog, a sunshine sensor that detects the degree of sunshine, and a snow sensor that detects snowfall. The surrounding information detection sensor may be at least one of an ultrasonic sensor, a radar device, and a light detection and ranging (laser imaging detection and ranging (LIDAR)) device. The image-capturing unit 7410 and the vehicle exterior information detector 7420 may be included as independent sensors or devices or may be included as a device in which a plurality of sensors or devices are integrated.

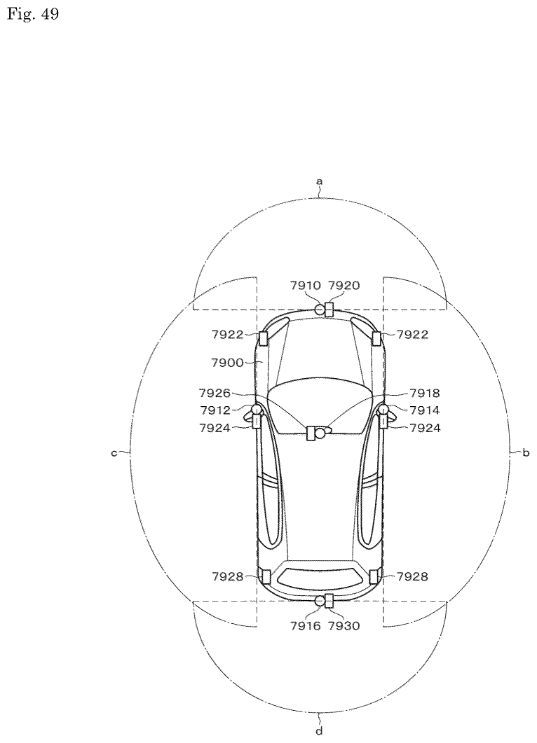

Here, FIG. 49 illustrates an example of the installation positions of the image-capturing unit 7410 and the vehicle exterior information detector 7420. Image-capturing units 7910, 7912, 7914, 7916, and 7918 are provided, for example, at at least one of a front nose, side mirrors, a rear bumper, a back door, and an upper part of a windshield in a vehicle cabin of the vehicle 7900. The image-capturing unit 7910 installed on the front nose and the image-capturing unit 7918 installed on the upper part of the windshield in the vehicle cabin mainly acquire images in front of the vehicle 7900. The image-capturing units 7912 and 7914 installed in the side mirrors mainly acquire images of the sides of the vehicle 7900. The image-capturing unit 7916 installed in the rear bumper or the back door mainly acquires images of the rear of the vehicle 7900. The image-capturing unit 7918 installed in the upper part of the windshield in the vehicle cabin is mainly used for detecting a preceding vehicle, a pedestrian, an obstacle, a traffic light, a traffic sign, a lane, or the like.

In FIG. 49, an example of shooting ranges of the respective image-capturing units 7910, 7912, 7914, and 7916 is illustrated. The image-capturing range a indicates an image-capturing range of the image-capturing unit 7910 provided on the front nose, image-capturing ranges b and c indicate image-capturing ranges of the image-capturing units 7912 and 7914 provided on the side mirrors, and the image capturing range d indicates an image-capturing range of the image-capturing unit 7916 provided on the rear bumper or the back door. For example, a bird's-eye view image of the vehicle 7900 as viewed from above can be obtained when the image data captured by the image-capturing units 7910, 7912, 7914, and 7916 are superimposed.

The vehicle exterior information detectors 7920, 7922, 7924, 7926, 7928, and 7930 provided on the front, rear, side, corners, and an upper part of the windshield in the vehicle cabin of the vehicle 7900 may be, for example, ultrasonic sensors or radar devices. The vehicle exterior information detectors 7920, 7926, and 7930 provided on the front nose, rear bumper, back door, and upper part of the windshield in the vehicle cabin of the vehicle 7900 may be, for example, LIDAR devices. These vehicle exterior information detectors 7920 to 7930 are mainly used for detecting preceding vehicles, pedestrians, obstacles, or the like.

The explanation will be continued with reference to FIG. 48 again. The vehicle exterior information detection unit 7400 causes the image-capturing unit 7410 to capture an image of the outside of the vehicle and receives the captured image data. Further, the vehicle exterior information detection unit 7400 receives detection information from the connected vehicle exterior information detector 7420. When the vehicle exterior information detector 7420 is an ultrasonic sensor, a radar device, or an LIDAR device, the vehicle exterior information detection unit 7400 transmits ultrasonic waves, electromagnetic waves, or the like and receives information on received reflected waves. The vehicle exterior information detection unit 7400 may perform object detection processing or distance detection processing for a person, a vehicle, an obstacle, a sign, or a character on a road surface on the basis of the received information. The vehicle exterior information detection unit 7400 may perform environment recognition processing for recognizing rainfall, fog, road surface situations, or the like on the basis of the received information. The vehicle exterior information detection unit 7400 may calculate the distance to an object outside of the vehicle on the basis of the received information.

Further, the vehicle exterior information detection unit 7400 may perform image recognition processing or distance detection processing for recognizing a person, a vehicle, an obstacle, a sign, a character on a road surface, or the like on the basis of the received image data. The vehicle exterior information detection unit 7400 may perform processing such as distortion correction or alignment on the received image data and combine image data captured by the different image-capturing units 7410 to generate a bird's-eye view image or a panoramic image. The vehicle exterior information detection unit 7400 may perform viewpoint conversion processing using the image data captured by the different image-capturing units 7410.

The vehicle interior information detection unit 7500 detects information inside of the vehicle. For example, a driver state detector 7510 that detects a driver's state is connected to the vehicle interior information detection unit 7500. The driver state detector 7510 may include a camera that captures images of a driver, a biological sensor that detects biological information on the driver, or a microphone that collects a sound in the vehicle cabin. For example, the biosensor is provided on a seat surface or a steering wheel and detects biological information of a passenger sitting on a seat or a driver holding the steering wheel. The vehicle interior information detection unit 7500 may calculate a degree of fatigue or a degree of concentration of the driver on the basis of detection information inputted from the driver state detector 7510 or may determine whether the driver is asleep. The vehicle interior information detection unit 7500 may perform processing such as noise canceling processing on the collected audio signal.

The integrated control unit 7600 controls overall operations in the vehicle control system 7000 according to various programs. An input unit 7800 is connected to the integrated control unit 7600. The input unit 7800 is implemented by a device that can be operated for the input by a passenger, for example, a touch panel, a button, a microphone, a switch, or a lever. Data obtained by recognizing voice inputted through a microphone may be inputted to the integrated control unit 7600. The input unit 7800 may be, for example, a remote control device using infrared rays or other radio waves, or may be an externally connected device such as a mobile phone or a personal digital assistant (PDA) in response to an operation on the vehicle control system 7000. The input unit 7800 may be, for example, a camera. In this case, the passenger can input information by gesture. Alternatively, data obtained by detecting the motion of a wearable device worn by the passenger may be inputted. Further, the input unit 7800 may include, for example, an input control circuit that generates an input signal on the basis of information inputted by the passenger or the like using the input unit 7800 and outputs the input signal to the integrated control unit 7600. The passenger or the like inputs various types of data to the vehicle control system 7000 or instructs a processing operation by operating the input unit 7800.

The storage unit 7690 may include a read-only memory (ROM) that stores various programs to be executed by a microcomputer, and a random access memory (RAM) that stores various parameters, calculation results, sensor values, or the like. The storage unit 7690 may be implemented by, for example, a magnetic storage device such as a hard disc drive (HDD), a semiconductor storage device, an optical storage device, or a magneto-optical storage device.

The general-purpose communication interface 7620 is a general-purpose communication interface that mediates communication with various devices present in an external environment 7750. The general-purpose communication interface 7620 may have, implemented therein, a cellular communication protocol such as global system of mobile (GSM) communications (registered trademark), WiMAX (registered trademark), long term evolution (LTE) (registered trademark), or LTE-Advanced (LTE-A), or other wireless communication protocols such as wireless LAN (also referred to as Wi-Fi (registered trademark)) or Bluetooth (registered trademark). The general-purpose communication interface 7620 may be connected to, for example, a device (for example, an application server or a control server) present on an external network (for example, the Internet, a cloud network, or a business-specific network) via a base station or an access point. The general-purpose communication interface 7620 may be connected to terminals (for example, the terminals of the driver, pedestrians, or shops, or machine-type communication (MTC) terminals) near the vehicle by using, for example, the peer-to-peer (P2P) technique.

The dedicated communication interface 7630 is a communication interface supporting a communication protocol formulated for the purpose of use in a vehicle. The dedicated communication interface 7630 may implement, for example, a standard protocol such as a wireless access in vehicle environment (WAVE) that is a combination of IEEE802.11p of a lower layer and IEEE1609 of an upper layer, a dedicated short range communications (DSRC), or a cellular communication protocol. The dedicated communication interface 7630 typically performs V2X communications as a concept including one or more of vehicle-to-vehicle communications, vehicle-to-infrastructure communications, vehicle-to-home communications, and vehicle-to-pedestrian communications.

The positioning unit 7640 receives, for example, a GNSS signal from a global navigation satellite system (GNSS) satellite (for example, a GPS signal from a global positioning system (GPS) satellite), executes positioning, and generates position information including the latitude, longitude, and altitude of the vehicle. The positioning unit 7640 may specify a current position by exchanging signals with a wireless access point, or may acquire position information from a terminal such as a mobile phone, PHS, or smartphone having a positioning function.

The beacon reception unit 7650 receives radio waves or electromagnetic waves transmitted from a radio station or the like installed on the road, and acquires information such as a current position, traffic jam, no thoroughfare, or required time. A function of the beacon reception unit 7650 may be included in the above-described dedicated communication interface 7630.

The in-vehicle device interface 7660 is a communication interface that mediates connections between the microcomputer 7610 and various in-vehicle devices 7760 present in the vehicle. The in-vehicle device interface 7660 may establish a wireless connection using wireless communication protocols such as a wireless LAN, Bluetooth (registered trademark), near field communication (NFC), and wireless USB (WUSB). Furthermore, the in-vehicle device interface 7660 may establish a wired connection of, for example, a universal serial bus (USB), high-definition multimedia interface (HDMI) (registered trademark), or mobile high-definition link (MHL) via a connection terminal (not illustrated, and a cable if necessary). The in-vehicle device 7760 may include, for example, at least one of a mobile device or wearable device of a passenger and an information device carried in or attached to the vehicle. Further, the in-vehicle device 7760 may include a navigation device that searches for a route to an arbitrary destination. The in-vehicle device interface 7660 exchanges control signals or data signals with the in-vehicle device 7760.

The vehicle-mounted network interface 7680 is an interface that mediates communication between the microcomputer 7610 and the communication network 7010. The vehicle-mounted network interface 7680 transmits and receives signals or the like in conformity with a predetermined protocol supported by the communication network 7010.

The microcomputer 7610 of the integrated control unit 7600 controls the vehicle control system 7000 in accordance with various programs on the basis of information acquired through at least one of the general-purpose communication interface 7620, the dedicated communication interface 7630, the positioning unit 7640, the beacon reception unit 7650, the in-vehicle device interface 7660, and the vehicle-mounted network interface 7680. For example, the microcomputer 7610 may calculate control target values for a driving force generation device, a steering mechanism, or a braking device on the basis of acquired information on the inside and outside of the vehicle, and output control commands to the driving system control unit 7100. For example, the microcomputer 7610 may perform cooperative control for the purpose of implementing the functions of an advanced driver assistance system (ADAS), the functions including vehicle collision avoidance or impact mitigation, follow-up traveling based on an inter-vehicle distance, vehicle speed maintenance driving, a vehicle collision warning, and a vehicle lane departure warning. The microcomputer 7610 may perform coordinated control for automated driving, in which a vehicle travels automatedly, not depending on the operation of a driver, by controlling, for example, a driving force generation device, a steering mechanism, or a braking device on the basis of acquired surrounding information on the vehicle.

The microcomputer 7610 may generate three-dimensional distance information between the vehicle and objects such as surrounding structures or people on the basis of information acquired via at least one of the general-purpose communication interface 7620, the dedicated communication interface 7630, the positioning unit 7640, the beacon reception unit 7650, the in-vehicle device interface 7660, and the vehicle-mounted network interface 7680 and may generate local map information including surrounding information of a present position of the vehicle. The microcomputer 7610 may predict hazards such as the collision of the vehicle, the approach of a pedestrian, or entry into a traffic prohibition road on the basis of the acquired information and may generate a warning signal. For example, the warning signal may be a signal for generating a warning sound or turning on a warning lamp.

The audio/image output unit 7670 transmits output signals of at least one of the audio and images to an output device capable of visually or audibly notifying a passenger of the vehicle or the outside of the vehicle of information. In the example of FIG. 48, an audio speaker 7710, a display unit 7720, and an instrument panel 7730 are illustrated as output devices. For example, the display unit 7720 may include at least one of an on-board display and a head-up display. The display unit 7720 may have an augmented reality (AR) display function. The output device may be other devices such as a headphone, a wearable device such as a glasses-type display worn by a passenger, a projector, and a lamp. When the output device is a display device, the display device visually displays results obtained through various processes performed by the microcomputer 7610 or information received from another control unit in various formats such as text, images, tables, and graphs. When the output device is a sound output device, the sound output device converts an audio signal formed by reproduced sound data, acoustic data, or the like into an analog signal and outputs the analog signal auditorily.

In the example illustrated in FIG. 48, at least two control units connected via the communication network 7010 may be integrated as one control unit. Alternatively, each control unit may be configured of a plurality of control units. Further, the vehicle control system 7000 may include another control unit that is not illustrated. Further, in the above explanation, the other control unit may have some or all of the functions of any one of the control units. That is, predetermined calculation processing may be performed by any one of the control units as long as the information is transmitted and received via the communication network 7010. Similarly, a sensor or device connected to any one of the control units may be connected to the other control unit, and a plurality of control units may transmit or receive detection information to and from each other via the communication network 7010.

In the vehicle control system 7000 described above, the semiconductor laser device of the present disclosure can be applied, for example, to a vehicle exterior information detector.

### REFERENCE SIGNS LIST

40 Semiconductor substrate
41A First principal plane
41B Second principal plane
50, 56, 58 Light-emitting unit
51 Lower DBR layer
52 Active layer
53 Upper DBR layer
61, 63, 64 Upper electrode
62, 65, 66 Lower electrode
71 First protective film
72 Second protective film
73 Third protective film
75 Fourth protective film
76 Fifth protective film
77 Sixth protective film
100, 100A Semiconductor laser device

1. A semiconductor laser device comprising:
a semiconductor substrate having a first principal plane and a second principal plane opposite to the first principal plane,
a plurality of light-emitting units disposed on the first principal plane,
a first electrode electrically connected to a first region that is one region when an active region of each of the light-emitting unit serves as a boundary, and
a second electrode electrically connected to a second region that is the other region when the active region of each of the light-emitting unit serves as the boundary,
wherein
the first electrode and the second electrode are stacked via an insulating film therebetween on the first principal plane along a thickness direction of the semiconductor substrate.

2. The semiconductor laser device according to claim 1, wherein
each of the light-emitting unit has a structure protruding with respect to the first principal plane, and
the first region is an upper side region, and the second region is a lower side region including a part in contact with the first principal plane.

3. The semiconductor laser device according to claim 2, wherein
when the light-emitting unit is viewed in a cross-section, the second region has a wide portion where a part in contact with the first principal plane is wide, and
the second electrode is electrically connected to the wide portion.

4. The semiconductor laser device according to claim 1, wherein
the first electrode and the second electrode are arranged along a substantially identical direction in the plane of the first principal plane.

5. The semiconductor laser device according to claim 1, wherein
a direction of a current flowing in the first electrode and a direction of a current flowing in the second electrode are opposite.

6. The semiconductor laser device according to claim 1, wherein
an outer shape of the first electrode and an outer shape of the second electrode are substantially identical.

7. The semiconductor laser device according to claim 1, further comprising a third electrode and a fourth electrode, wherein
a plurality of first light-emitting units and a plurality of second light-emitting units are disposed on the first principal plane,
the first electrode is electrically connected to a first region that is one region when an active region of each of the first light-emitting unit serves as a boundary,
the second electrode is electrically connected to a second region that is the other region when the active region of each of the first light-emitting unit serves as the boundary,
the third electrode is electrically connected to a third region that is one region when an active region of each of the second light-emitting unit serves as a boundary,
the fourth electrode is electrically connected to a fourth region that is the other region when the active region of each of the second light-emitting unit serves as the boundary, and
the third electrode and the fourth electrode are stacked via an insulating film therebetween on the first principal plane along the thickness direction of the semiconductor substrate.

8. The semiconductor laser device according to claim 7, wherein
an insulating film is disposed between the third electrode and fourth electrode and the first light-emitting units.

9. The semiconductor laser device according to claim 7, wherein
a direction of a current flowing in the first electrode and a direction of a current flowing in the second electrode are opposite, and
a direction of a current flowing in the third electrode and a direction of a current flowing in the fourth electrode are opposite.

10. The semiconductor laser device according to claim 9, wherein
the direction of the current flowing in the first electrode and the direction of the current flowing in the third electrode are opposite, and
the direction of the current flowing in the second electrode and the direction of the current flowing in the fourth electrode are opposite.

11. The semiconductor laser device according to claim 7, wherein
the first electrode and the third electrode are not electrically connected, and the second electrode and the fourth electrode are not electrically connected.

12. The semiconductor laser device according to claim 1, wherein
the semiconductor substrate is a semi-insulating substrate.

13. The semiconductor laser device according to claim 1, wherein
a plurality of array structures including each of the light-emitting unit and the first electrode and second electrode electrically connected to the light-emitting unit are disposed on the first principal plane.

14. A distance measurement device comprising the semiconductor laser device according to claim 1.

15. A vehicle-mounted device comprising the distance measurement device according to claim 14.
